(19) United States
(12) Patent Application Publication
(10) Pub. No.: US 2026/0290406 A1
(43) Pub. Date: Sep. 24, 2026

(54) MEMORY DEVICE

(71) Applicant: Kioxia Corporation, Tokyo (JP)

(72) Inventors: Ryota NIHEI, Yokkaichi (JP); Kouji MATSUO, Ama (JP); Yuta SAITO, Yokkaichi (JP)

(21) Appl. No.: 19/323,348

(22) Filed: Sep. 9, 2025

(30) Foreign Application Priority Data
Mar. 21, 2025 (JP) 2025-046665

(51) Int. Cl. G11C 5/06; G11C 16/04; H10B 41/10; H10B 41/35

(52) U.S. Cl. CPC G11C 5/063; G11C 16/0483; H10B 41/10; H10B 41/35

(57) ABSTRACT

According to one embodiment, a memory device includes a first conductive pillar, a second conductive pillar, and a third conductive pillar each extending in a first direction, a first semiconductor film surrounding the first conductive pillar at a first position in the first direction, a second semiconductor film partially surrounding the second conductive pillar at the first position, a third semiconductor film partially surrounding the third conductive pillar at the first position, a fourth semiconductor film in contact with each of the first semiconductor film, a first end of the second semiconductor film, and a first end of the third semiconductor film, a first charge storage film provided between the second conductive pillar and the second semiconductor film, and a second charge storage film provided between the third conductive pillar and the third semiconductor film.

### CROSS-REFERENCE TO RELATED APPLICATION

This application is based upon and claims the benefit of priority from Japanese Patent Application No. 2025-046665, filed Mar. 21, 2025, the entire contents of which are incorporated herein by reference.

### FIELD

Embodiments described herein relate generally to a memory device.

### BACKGROUND

A NAND flash memory is known as a memory device capable of storing data in a non-volatile manner. In a memory device such as a NAND flash memory, a three-dimensional memory structure is adopted for higher integration and larger capacity.

### DESCRIPTION OF THE DRAWINGS

FIG. 1 is a block diagram showing an example of a configuration of a memory system including a memory device according to an embodiment;

FIG. 2 is a circuit diagram showing an example of a circuit configuration of a memory cell array in the memory device according to the embodiment;

FIG. 3 is a plan view showing an example of a planar layout of the memory cell array according to the embodiment;

FIG. 4 is a cross-sectional view taken along a line IV-IV in FIG. 3, showing an example of a cross-sectional structure of the memory cell array according to the embodiment;

FIG. 5 is a plan view showing an example of a planar layout of the memory device during manufacture according to the embodiment;

FIG. 6 is a cross-sectional view showing an example of a cross-sectional structure of the memory device during manufacture according to the embodiment;

FIG. 7 is a plan view showing an example of a planar layout of the memory device during manufacture according to the embodiment;

FIG. 8 is a cross-sectional view showing an example of a cross-sectional structure of the memory device during manufacture according to the embodiment;

FIG. 9 is a plan view showing an example of a planar layout of the memory device during manufacture according to the embodiment;

FIG. 10 is a cross-sectional view showing an example of a cross-sectional structure of the memory device during manufacture according to the embodiment;

FIG. 11 is a plan view showing an example of a planar layout of the memory device during manufacture according to the embodiment;

FIG. 12 is a cross-sectional view showing an example of a cross-sectional structure of the memory device during manufacture according to the embodiment;

FIG. 13 is a plan view showing an example of a planar layout of the memory device during manufacture according to the embodiment;

FIG. 14 is a cross-sectional view showing an example of a cross-sectional structure of the memory device during manufacture according to the embodiment;

FIG. 15 is a plan view showing an example of a planar layout of the memory device during manufacture according to the embodiment;

FIG. 16 is a cross-sectional view showing an example of a cross-sectional structure of the memory device during manufacture according to the embodiment;

FIG. 17 is a plan view showing an example of a planar layout of the memory device during manufacture according to the embodiment;

FIG. 18 is a cross-sectional view showing an example of a cross-sectional structure of the memory device during manufacture according to the embodiment;

FIG. 19 is a plan view showing an example of a planar layout of the memory device during manufacture according to the embodiment;

FIG. 20 is a cross-sectional view showing an example of a cross-sectional structure of the memory device during manufacture according to the embodiment;

FIG. 21 is a plan view showing an example of a planar layout of the memory device during manufacture according to the embodiment;

FIG. 22 is a cross-sectional view showing an example of a cross-sectional structure of the memory device during manufacture according to the embodiment;

FIG. 23 is a plan view showing an example of a planar layout of the memory device during manufacture according to the embodiment;

FIG. 24 is a cross-sectional view showing an example of a cross-sectional structure of the memory device during manufacture according to the embodiment;

FIG. 25 is a plan view showing an example of a planar layout of the memory device during manufacture according to the embodiment;

FIG. 26 is a cross-sectional view showing an example of a cross-sectional structure of the memory device during manufacture according to the embodiment;

FIG. 27 is a plan view showing an example of a planar layout of the memory device during manufacture according to the embodiment;

FIG. 28 is a cross-sectional view showing an example of a cross-sectional structure of the memory device during manufacture according to the embodiment;

FIG. 29 is a plan view showing an example of a planar layout of the memory device during manufacture according to the embodiment;

FIG. 30 is a cross-sectional view showing an example of a cross-sectional structure of the memory device during manufacture according to the embodiment;

FIG. 31 is a plan view showing an example of a planar layout of the memory device during manufacture according to the embodiment;

FIG. 32 is a cross-sectional view showing an example of a cross-sectional structure of the memory device during manufacture according to the embodiment;

FIG. 33 is a plan view showing an example of a planar layout of the memory device during manufacture according to the embodiment;

FIG. 34 is a cross-sectional view showing an example of a cross-sectional structure of the memory device during manufacture according to the embodiment;

FIG. 35 is a plan view showing an example of a planar layout of the memory device during manufacture according to the embodiment;

FIG. 36 is a cross-sectional view showing an example of a cross-sectional structure of the memory device during manufacture according to the embodiment;

FIG. 37 is a plan view showing an example of a planar layout of the memory device during manufacture according to the embodiment;

FIG. 38 is a cross-sectional view showing an example of a cross-sectional structure of the memory device during manufacture according to the embodiment;

FIG. 39 is a plan view showing an example of a planar layout of the memory device during manufacture according to the embodiment;

FIG. 40 is a cross-sectional view showing an example of a cross-sectional structure of the memory device during manufacture according to the embodiment;

FIG. 41 is a plan view showing an example of a planar layout of the memory device during manufacture according to the embodiment;

FIG. 42 is a cross-sectional view showing an example of a cross-sectional structure of the memory device during manufacture according to the embodiment;

FIG. 43 is a plan view showing an example of a planar layout of the memory device during manufacture according to the embodiment;

FIG. 44 is a cross-sectional view showing an example of a cross-sectional structure of the memory device during manufacture according to the embodiment;

FIG. 45 is a plan view showing an example of a planar layout of the memory device during manufacture according to the embodiment;

FIG. 46 is a cross-sectional view showing an example of a cross-sectional structure of the memory device during manufacture according to the embodiment;

FIG. 47 is a plan view showing an example of a planar layout of the memory device during manufacture according to the embodiment;

FIG. 48 is a cross-sectional view showing an example of a cross-sectional structure of the memory device during manufacture according to the embodiment;

FIG. 49 is a plan view showing an example of a planar layout of the memory device during manufacture according to the embodiment;

FIG. 50 is a cross-sectional view showing an example of a cross-sectional structure of the memory device during manufacture according to the embodiment;

FIG. 51 is a plan view showing an example of a planar layout of the memory device during manufacture according to the embodiment;

FIG. 52 is a cross-sectional view showing an example of a cross-sectional structure of the memory device during manufacture according to the embodiment;

FIG. 53 is a plan view showing an example of a planar layout of the memory device during manufacture according to the embodiment;

FIG. 54 is a cross-sectional view showing an example of a cross-sectional structure of the memory device during manufacture according to the embodiment;

FIG. 55 is a plan view showing an example of a planar layout of the memory device during manufacture according to the embodiment;

FIG. 56 is a cross-sectional view showing an example of a cross-sectional structure of the memory device during manufacture according to the embodiment;

FIG. 57 is a plan view showing an example of a planar layout of the memory device during manufacture according to the embodiment;

FIG. 58 is a cross-sectional view showing an example of a cross-sectional structure of the memory device during manufacture according to the embodiment; and

FIG. 59 is a plan view showing an example of a planar layout of a memory cell array according to a modification.

### DETAILED DESCRIPTION

Embodiments provide a memory device with an improved integration density.

In general, according to one embodiment, a memory device includes a first conductive pillar, a second conductive pillar, and a third conductive pillar each extending in a first direction, a first semiconductor film surrounding the first conductive pillar at a first position in the first direction, a second semiconductor film partially surrounding the second conductive pillar at the first position, a third semiconductor film partially surrounding the third conductive pillar at the first position, a fourth semiconductor film in contact with each of the first semiconductor film, a first end of the second semiconductor film, and a first end of the third semiconductor film, a first charge storage film provided between the second conductive pillar and the second semiconductor film, and a second charge storage film provided between the third conductive pillar and the third semiconductor film.

Hereinafter, an embodiment will be described with reference to drawings. Dimensions and proportions of the drawings are not necessarily drawn in actual scales.

In the following description, components having substantially the same functions and configurations are denoted by the same reference numerals. Different letters or numerals may be added to the end of the same reference numerals to specifically distinguish between components having similar configurations.

### 1. Configuration

### 1.1 Memory System

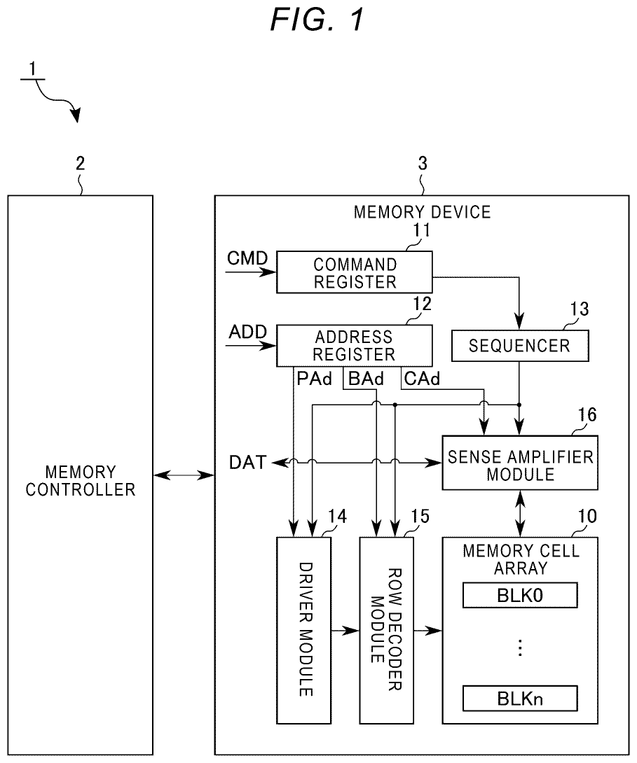

FIG. 1 is a block diagram showing an example of a configuration of a memory system including a memory device according to the embodiment. A memory system 1 is a storage device configured to be connected to an external host (not shown). The memory system 1 is, for example, a memory card such as an SD™ card, a universal flash storage (UFS), or a solid state drive (SSD). The memory system 1 includes a memory controller 2 and a memory device 3.

The memory controller 2 includes, for example, an integrated circuit such as a system-on-a-chip (SoC). The memory controller 2 controls the memory device 3 based on a request from the host. Specifically, for example, the memory controller 2 writes data requested to be written by the host to the memory device 3. The memory controller 2 reads data requested to be read by the host from the memory device 3 and transmits the read data to the host.

The memory device 3 is a non-volatile memory. The memory device 3 is, for example, a NAND flash memory. The memory device 3 stores data in a non-volatile manner.

Communication between the memory controller 2 and the memory device 3 is, for example, in compliance with a single data rate (SDR) interface, a toggle double data rate (DDR) interface, or an open NAND flash interface (ONFI).

### 1.2 Memory Device

Next, an internal configuration of the memory device according to the embodiment will be described with reference to the block diagram shown in FIG. 1. The memory device 3 includes, for example, a memory cell array 10, a command register 11, an address register 12, a sequencer 13, a driver module 14, a row decoder module 15, and a sense amplifier module 16.

The memory cell array 10 includes a plurality of blocks BLK0 to BLKn (n is an integer equal to or greater than 1). The number of blocks BLK in the memory cell array 10 may be one. The block BLK is a set including a plurality of memory cells. The block BLK is used, for example, as a unit of data erasure. The memory cell array 10 includes a plurality of bit lines and a plurality of word lines. Each memory cell is associated with one bit line and one word line, for example. A detailed configuration of the memory cell array 10 will be described below.

The command register 11 stores a command CMD that the memory device 3 received from the memory controller 2. For example, the command CMD includes an instruction for causing the sequencer 13 to execute a read operation, a write operation, an erase operation, and the like.

The address register 12 stores address information ADD that the memory device 3 received from the memory controller 2. The address information ADD includes, for example, a block address BAd, a page address PAd, and a column address CAd. For example, the block address BAd, the page address PAd, and the column address CAd are used to select a block BLK, a word line, and a bit line, respectively.

The sequencer 13 controls an overall operation of the memory device 3. For example, the sequencer 13 controls the driver module 14, the row decoder module 15, the sense amplifier module 16, and the like based on the command CMD stored in the command register 11 and executes the read operation, the write operation, the erase operation, and the like.

The driver module 14 generates voltages to be used in the read operation, the write operation, the erase operation, and the like. Then, the driver module 14 applies the generated voltage to a signal line corresponding to the selected word line based on the page address PAd stored in the address register 12, for example.

The row decoder module 15 selects one block BLK in the corresponding memory cell array 10 based on the block address BAd stored in the address register 12. Then, the row decoder module 15 transfers, for example, the voltage applied to the signal line corresponding to the selected word line to the selected word line in the selected block BLK.

In the write operation, the sense amplifier module 16 applies a desired voltage to each bit line according to write data DAT received from the memory controller 2. In the read operation, the sense amplifier module 16 determines data stored in the memory cell based on a voltage of the bit line and transfers the determination result to the memory controller 2 as read data DAT.

### 1.3 Memory Cell Array

### 1.3.1 Circuit Configuration

Next, a circuit configuration of the memory cell array according to the embodiment will be described.

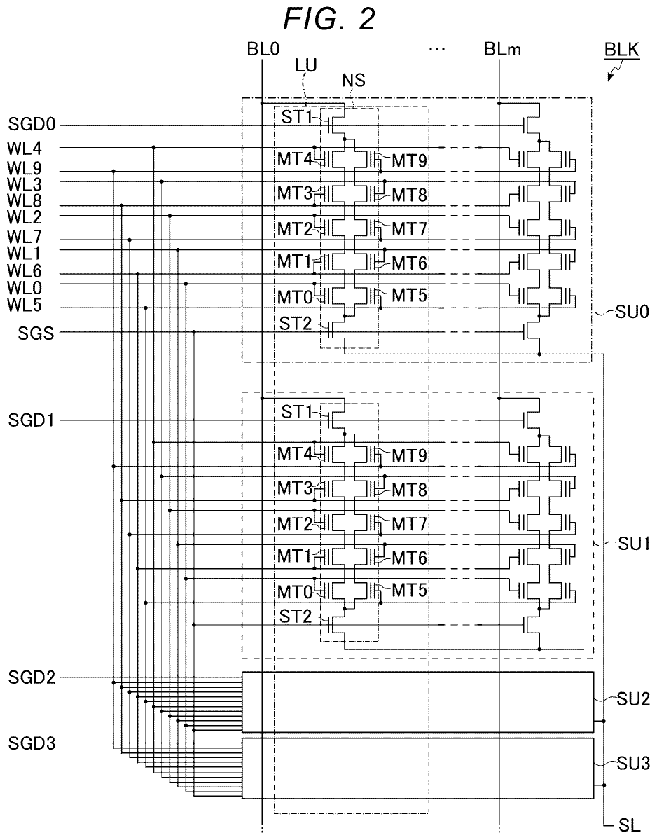

FIG. 2 is a circuit diagram showing an example of the circuit configuration of the memory cell array in the memory device according to the embodiment. FIG. 2 shows one block BLK among the plurality of blocks BLK in the memory cell array 10. As shown in FIG. 2, the block BLK includes four string units (SU0 to SU3), for example.

Each string unit SU includes a plurality of NAND strings NS each associated with each of bit lines BL0 to BLm (m is an integer equal to or greater than 1). The number of bit lines BL may be one. For example, each NAND string NS includes memory cell transistors MT0 to MT9 and select transistors ST1 and ST2. Each memory cell transistor MT includes a control gate and a charge storage film and stores data in a non-volatile manner. The select transistors ST1 and ST2 are used for selecting a string unit SU during various operations.

In each NAND string NS, the memory cell transistors MT0 to MT9 form two current paths between the select transistors ST1 and ST2. Specifically, the memory cell transistors MT0 to MT4 are connected in series to form one current path. The memory cell transistors MT5 to MT9 are connected in series to form one current path different from the current path of the memory cell transistors MT0 to MT4. A drain of the select transistor ST1 is connected to the associated bit line BL. A source of the select transistor ST1 is connected to one end of the series-connected memory cell transistors MT0 to MT4 and to one end of the series-connected memory cell transistors MT5 to MT9. A drain of the select transistor ST2 is connected to the other end of the series-connected memory cell transistors MT0 to MT4 and to the other end of the series-connected memory cell transistors MT5 to MT9. A source of the select transistor ST2 is connected to a source line SL. That is, the memory cell transistors MT0 to MT4 are connected in parallel to the memory cell transistors MT5 to MT9 between the select transistors ST1 and ST2.

In the same block BLK, control gates of the memory cell transistors MT0 to MT9 are each connected to word lines WL0 to WL9. Gates of the select transistors ST1 in the string units SU0 to SU3 are each connected to select gate lines SGD0 to SGD3. Gates of a plurality of select transistors ST2 are connected to a select gate line SGS.

Different column addresses are allocated to each of the bit lines BL0 to BLm. Each bit line BL is shared by the NAND strings NS to which the same column address is allocated between the plurality of blocks BLK. The word lines WL0 to WL9 are provided for each block BLK. The source line SL is shared between the plurality of blocks BLK, for example.

For example, a set including a plurality of memory cell transistors MT connected to a common word line WL in one string unit SU is referred to as a cell unit. For example, a memory capacity of the cell unit including the memory cell transistors MT each storing 1-bit data is defined as “1-page data”. The cell unit may have a memory capacity of 2-page data or more depending on the number of bits of data stored in the memory cell transistors MT.

A set including a plurality of memory cell transistors MT connected to a common bit line BL in one block BLK is referred to as a layer unit LU, for example. One layer unit LU includes four NAND strings NS. The four NAND strings NS in one layer unit LU each belong to the string units SU0 to SU3.

The circuit configuration of the memory cell array 10 in the memory device 3 is not limited to the configuration described above. For example, the number of string units SU provided in each block BLK may be set to any desired number. The number of memory cell transistors MT provided in each NAND string NS and the number of select transistors ST1 and ST2 may be designed to any desired number.

### 1.3.2 Planar Layout

Next, a planar layout of the memory cell array according to the embodiment will be described.

The memory cell array 10 is provided above a substrate. Hereinafter, a plane parallel to a surface of the substrate is defined as an XY plane. A direction in which the word line WL extends in the XY plane is defined as an X direction. A direction orthogonal to the X direction in the XY plane is defined as a Y direction. A direction from the substrate toward the memory cell array is defined as a Z direction. The Z direction may be considered as an upward direction.

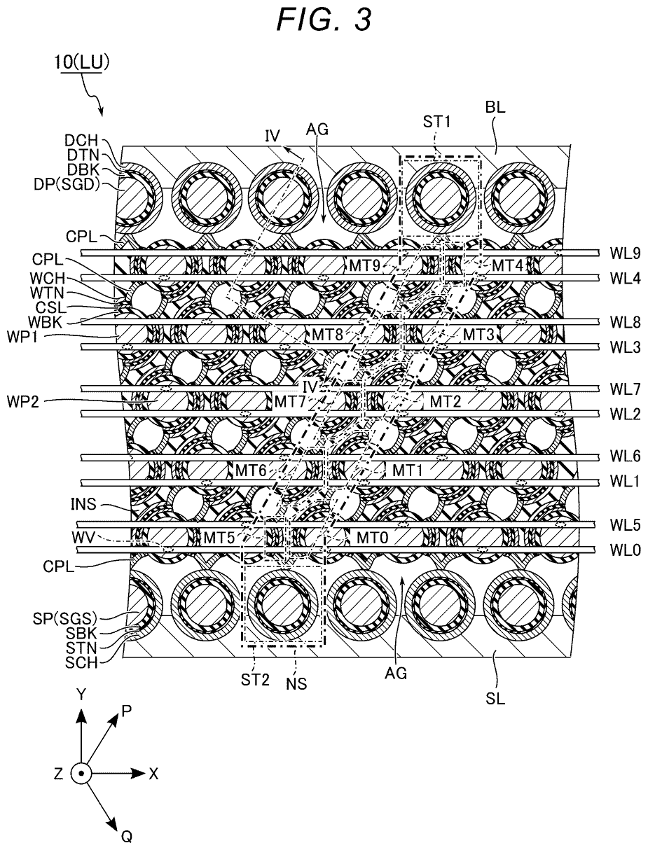

FIG. 3 is a plan view showing an example of the planar layout of the memory cell array according to the embodiment. FIG. 3 shows a plan view of a position (layer) in a structure configuring the memory cell array 10 located at approximately the same position in the Z direction from the substrate (in the XY plane) and including a structure that functions as a NAND string NS. A portion shown in FIG. 3 corresponds to one layer unit LU in the circuit diagram shown in FIG. 2.

As shown in FIG. 3, in the same layer, the memory cell array 10 includes a plurality of conductive pillars WP1, WP2, DP, and SP, a plurality of block insulating films WBK, DBK, and SBK, a plurality of charge storage films CSL, a plurality of tunnel insulating films WTN, DTN, and STN, a plurality of channel films WCH, DCH, and SCH, a plurality of current path films CPL, a plurality of insulators INS, a plurality of contacts WV, a plurality of word lines WL, and bit lines BL.

Each of the plurality of conductive pillars WP1, WP2, DP, and SP is a conductor having a columnar shape extending in the Z direction. The plurality of conductive pillars WP1, WP2, DP, and SP are arranged in a matrix configuration in two directions different from the X direction and the Y direction in the XY plane. Hereinafter, a P direction and a Q direction different from the X direction and the Y direction are defined as arrangement directions of the plurality of conductive pillars WP1, WP2, DP, and SP.

In the example of FIG. 3, seven conductive pillars DP, WP1, WP1, WP1, WP1, WP1, and SP are arranged in the P direction in this order. Then, seven conductive pillars DP, WP2, WP2, WP2, WP2, WP2, and SP are arranged in this order in the P direction to be adjacent in the X direction to the seven conductive pillars DP, WP1, WP1, WP1, WP1, WP1, and SP arranged in this order in the P direction. A set including seven conductive pillars DP, WP1, WP1, WP1, WP1, WP1, and SP arranged in the P direction and a set including seven conductive pillars DP, WP2, WP2, WP2, WP2, WP2 and SP arranged in the P direction are alternately disposed in the X direction.

When viewed in the Q direction, the arrangement described above is also described as follows. That is, the seven conductive pillars DP, WP1, WP2, WP1, WP2, WP1, and SP are arranged in this order in the Q direction. Then, seven conductive pillars DP, WP2, WP1, WP2, WP1, WP2, and SP are arranged in this order in the Q direction to be adjacent in the X direction to the seven conductive pillars DP, WP1, WP2, WP1, WP2, WP1, and SP arranged in this order in the Q direction. A set including seven conductive pillars DP, WP1, WP2, WP1, WP2, WP1, and SP arranged in the Q direction and a set including seven conductive pillars DP, WP2, WP1, WP2, WP1, WP2, and SP arranged in the Q direction are alternately disposed in the X direction.

When viewed in the Z direction, the block insulating film WBK is provided to surround an outer periphery of each of the conductive pillars WP1 and WP2. Two charge storage films CSL are provided separately from each other and partially surround an outer periphery of the block insulating film WBK. The two charge storage films CSL partially surrounding the outer periphery of a certain block insulating film WBK face each other in the Q direction. Two portions not surrounded by the charge storage film CSL in the outer periphery of the block insulating film WBK face each other in the P direction. The tunnel insulating film WTN is provided to surround an outer periphery of the charge storage film CSL. The channel film WCH is provided to surround an outer periphery of the tunnel insulating film WTN. As described above, two stacked sets including the charge storage film CSL, the tunnel insulating film WTN, and the channel film WCH are provided separately from each other and face the block insulating film WBK in the Q direction. Hereinafter, a stacked film including the block insulating film WBK, the charge storage film CSL, the tunnel insulating film WTN, and the channel film WCH is also referred to as an MT stacked film.

The conductive pillar WP1 or WP2 and one MT stacked film function as one memory cell transistor MT. That is, the conductive pillar WP1 or WP2 functions as a gate electrode in the memory cell transistor MT electrically connected to the word line WL. The conductive pillars WP1 and WP2 are shared as gate electrodes of two memory cell transistors MT corresponding to two memory films provided separately from each other.

When viewed in the Z direction, the block insulating film SBK is provided to surround an outer periphery of each of the conductive pillars SP. The tunnel insulating film STN is provided to surround the outer periphery of the block insulating film SBK. The channel film SCH is provided to surround an outer periphery of the tunnel insulating film STN. As described above, one stacked set including the block insulating film SBK, the tunnel insulating film STN, and the channel film SCH is provided for each conductive pillar SP. In the following description, a stacked film including the block insulating film SBK, the tunnel insulating film STN, and the channel film SCH is also referred to as an ST stacked film.

The conductive pillar SP and one ST stacked film function as one select transistor ST1. That is, the conductive pillar SP functions as a gate electrode in the select transistor ST1 electrically connected to the select gate line SGS.

When viewed in the Z direction, the block insulating film DBK is provided to surround an outer periphery of each of the conductive pillars DP. The tunnel insulating film DTN is provided to surround an outer periphery of the block insulating film DBK. The channel film DCH is provided to surround an outer periphery of the tunnel insulating film DTN. As described above, one stacked set including the block insulating film DBK, the tunnel insulating film DTN, and the channel film DCH is provided for each conductive pillar DP. In the following description, a stacked film including the block insulating film DBK, the tunnel insulating film DTN, and the channel film DCH is also referred to as an ST stacked film same as the stacked film including the block insulating film SBK, the tunnel insulating film STN, and the channel film SCH.

The conductive pillar DP and one ST stacked film function as one select transistor ST2. That is, the conductive pillar DP functions as a gate electrode in the select transistor ST2 electrically connected to the select gate line SGD.

Each of the two channel films WCH corresponding to the conductive pillar WP1 is connected to the two channel films WCH corresponding to the conductive pillar WP1 adjacent in the P direction via two separate current path films CPL. Each of the two channel films WCH corresponding to the conductive pillar WP2 is connected to the two channel films WCH corresponding to the conductive pillar WP2 adjacent in the P direction via two separate current path films CPL. The channel film DCH corresponding to the conductive pillar DP is commonly connected to one of two channel films WCH corresponding to the conductive pillar WP1 adjacent in the P direction or the Q direction and one of two channel films WCH corresponding to the conductive pillar WP2 adjacent in the P direction or the Q direction via the current path film CPL. The channel film SCH corresponding to the conductive pillar SP is commonly connected to one of two channel films WCH corresponding to the conductive pillar WP1 adjacent in the P direction or the Q direction and one of two channel films WCH corresponding to the conductive pillar WP2 adjacent in the P direction or the Q direction via the current path film CPL.

As described above, five conductive pillars WP1 arranged in the P directionform two independent current paths, which extend in the P direction respectively fand face each other in the Q direction. The two current paths are each connected to different sets including the channel films DCH and SCH.

A plurality of channel films SCH corresponding to a plurality of conductive pillars SP arranged in the X direction are commonly connected to the source line SL.

A plurality of channel films DCH corresponding to a plurality of conductive pillars DP arranged in the X direction are commonly connected to the bit line BL.

According to the structure described above, between a pair of select transistors ST1 and ST2, the NAND string NS in which two sets each including five memory cell transistors MT connected in series in the P direction are connected in parallel is implemented.

The insulator INS is provided in a portion surrounded by the plurality of current path films CPL and the plurality of channel films WCH. An air gap AG is provided in a portion surrounded by two conductive pillars WP1 or WP2 adjacent in the P direction and two current path films CPL connecting two channel films WCH corresponding to the two conductive pillars WP1 or WP2. The air gap AG is provided in a portion surrounded by two conductive pillars DP and one conductive pillar WP1 or WP2 connected to each of the two conductive pillars DP. The air gap AG is provided in a portion surrounded by two conductive pillars SP and one conductive pillar WP1 or WP2 connected to each of the two conductive pillars SP.

The contact WV is provided on an upper surface of each of the plurality of conductive pillars WP1 and WP2. The plurality of contacts WV provided on each of the plurality of conductive pillars WP1 arranged in the X direction are connected to a common word line WL. The plurality of contacts WV provided on each of the plurality of conductive pillars WP2 arranged in the X direction are connected to a common word line WL.

### 1.3.3 Cross-Sectional Structure

Next, a cross-sectional structure of the memory cell array according to the embodiment will be described.

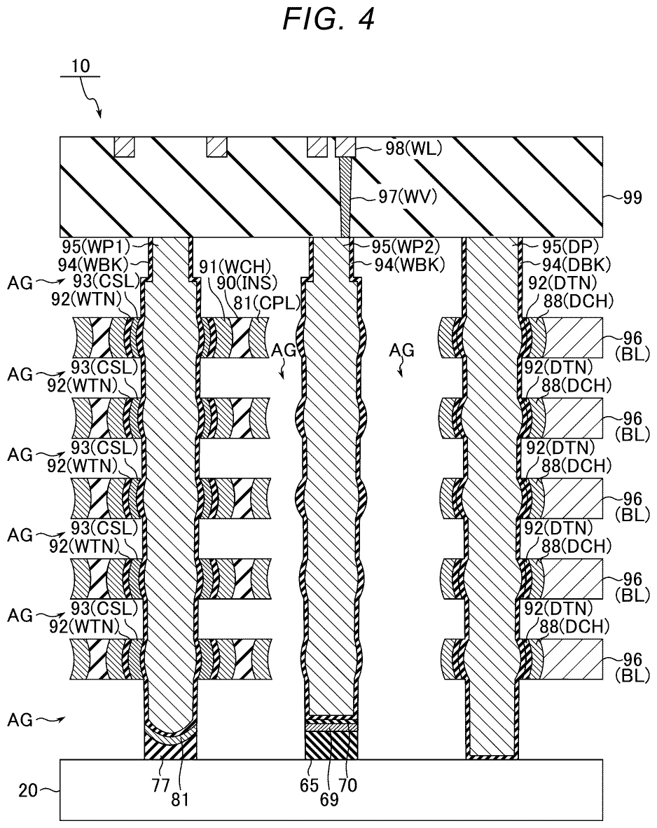

FIG. 4 is a cross-sectional view taken along a line IV-IV of FIG. 3, showing an example of the cross-sectional structure of the memory cell array according to the embodiment. FIG. 4 mainly shows a cross-sectional structure including the conductive pillars WP1, WP2, and DP. The conductive pillar WP1 shown in FIG. 4 is a structure on the left side of the drawing, and a cross-section including two corresponding memory films is shown. The conductive pillar WP2 shown in FIG. 4 is a structure at the center of the drawing and a cross-section not including the two corresponding memory films (that is, a cross-section of a portion surrounded by the air gap AG) is shown. The conductive pillar DP shown in FIG. 4 is a structure on the right side of the drawing and a cross-section not including the corresponding current path film CPL is shown.

As shown in FIG. 4, the memory cell array 10 includes a substrate 20, sacrificial films 65 and 77, semiconductor films 69, 81, 88, 91, and 93, conductor films 95 and 97, insulator films 70, 90, 92, and 94, conductor layers 96 and 98, and an insulator layer 99.

The substrate 20 is, for example, a semiconductor substrate including silicon.

A plurality of conductor films 95 are provided above the substrate 20. Each of the plurality of conductor films 95 extends in the Z direction. The plurality of conductor films 95 function as the conductive pillars WP1, WP2, and DP, and the conductive pillar SP (not shown). Each of the plurality of conductor films 95 includes, for example, tungsten or molybdenum.

The insulator film 94 is provided to cover a lower surface and side surfaces of each of the plurality of conductor films 95. The insulator film 94 corresponding to the conductor film 95 functioning as the conductive pillar WP1 or WP2 functions as the block insulating film WBK. The insulator film 94 corresponding to the conductor film 95 functioning as the conductive pillar DP functions as the block insulating film DBK. The insulator film 94 corresponding to the conductor film 95 functioning as the conductive pillar SP (not shown) functions as the block insulating film SBK. Each of the plurality of insulator films 94 includes, for example, silicon oxide.

The insulator films 94 covering the conductor film 95 corresponding to the conductive pillar DP or the conductive pillar SP (not shown) among the plurality of insulator films 94 are each in contact with the substrate 20 at a lower portion thereof. The sacrificial film 65, the semiconductor film 69, and the insulator film 70 are stacked in this order from the substrate 20 side between the insulator films 94 covering the conductor film 95 corresponding to the conductive pillar WP2 among the plurality of insulator films 94 and the substrate 20. The sacrificial film 77 and the semiconductor film 81 are stacked in this order from the substrate 20 side between each insulator film 94 that covers the conductor film 95 corresponding to the conductive pillar WP1 among the plurality of insulator films 94 and the substrate 20. The sacrificial films 65 and 77 include, for example, polysilicon. The semiconductor films 69 and 81 include, for example, silicon germanium. The insulator film 70 includes, for example, silicon oxide. The insulator film 70 may further include germanium.

The conductor film 97 is provided on an upper surface of the conductor film 95 functioning as the conductive pillar WP1 or WP2. The conductor film 97 functions as the contact WV. The conductor layer 98 is provided on an upper surface of the conductor film 97. The conductor layer 98 functions as the word line WL. For example, the conductor film 97 and the conductor layer 98 are covered with the insulator layer 99.

A plurality of layers are provided separately from each other in the Z direction with the air gap AG interposed therebetween to intersect each of the plurality of conductor films 95. Each of the plurality of layers corresponds to the layer unit LU. In the following description, a configuration corresponding to one layer unit LU will be described.

First, a configuration corresponding to the conductive pillar DP shown in FIG. 4 will be described.

In a certain layer, the insulator film 92 and the semiconductor film 88 are stacked in this order on a side surface of the insulator film 94 corresponding to the conductive pillar DP. The insulator film 92 includes, for example, silicon oxide and functions as the tunnel insulating film DTN. The semiconductor film 88 includes, for example, polysilicon and functions as the channel film DCH.

The conductor layer 96 and a semiconductor film (not shown) are provided separately from each other on a portion of a side surface of the semiconductor film 88. The conductor layer 96 functions as the bit line BL. The semiconductor film (not shown) functions as the current path film CPL. The air gap AG is provided at a portion on a side surface of the semiconductor film 88 at which the conductor layer 96 and the semiconductor film (not shown) are not provided.

A configuration corresponding to the insulator film 92 and the semiconductor film 88 described above is also similarly provided for the conductive pillar SP in a cross-section not shown.

Next, a configuration corresponding to the conductive pillar WP1 shown in FIG. 4 will be described.

In a certain layer, two semiconductor films 93 are provided separately from each other on a side surface of the insulator film 94 corresponding to the conductive pillar WP1. Each of the two semiconductor films 93 includes, for example, polysilicon and functions as a floating gate type charge storage film CSL.

The insulator film 92 is provided on a side surface of each of the two semiconductor films 93. Each of the two insulator films 92 includes, for example, silicon oxide and functions as the tunnel insulating film WTN.

The semiconductor film 91 is provided on a side surface of each of the two insulator films 92. Each of the two semiconductor films 91 includes, for example, polysilicon and functions as the channel film WCH.

The insulator film 90 is provided on a side surface of each of the two semiconductor films 91. Each of the two insulator films 90 includes, for example, silicon oxide and functions as the insulator INS.

A configuration corresponding to each of two sets including the insulator film 90, the semiconductor film 91, the insulator film 92, and the semiconductor film 93 described above is also similarly provided for the conductive pillar WP2 in a cross-section not shown.

Next, a configuration corresponding to the conductive pillar WP2 shown in FIG. 4 will be described.

In a certain layer, two air gaps AG are provided separately from each other on a side surface of the insulator film 94 corresponding to the conductive pillar WP2. The two air gaps AG are connected to each other via the air gaps AG between layers.

At least one of the two air gaps AG described above is surrounded by two insulator films 94 each corresponding to two conductive pillars WP2 adjacent to each other in the P direction, and two semiconductor films 81 connecting the two conductive pillars WP2 adjacent to each other in the P direction. Each of the two semiconductor films 81 is in contact with the insulator film 90 on a side surface facing the air gap AG. FIG. 4 shows one of the two semiconductor films 81. Each of the two semiconductor films 81 includes, for example, polysilicon and functions as the current path film CPL.

The other of the two air gaps AG may be surrounded by the insulator film 94 corresponding to the conductive pillar WP2, the semiconductor film 88 corresponding to the conductive pillar DP or SP adjacent to the conductive pillar WP2 in the P direction, and the semiconductor film 88 corresponding to the conductive pillar DP or SP adjacent to the conductive pillar WP2 in the Q direction. FIG. 4 shows the semiconductor film 88 corresponding to the conductive pillar DP adjacent to the conductive pillar WP2 in the P direction.

A configuration corresponding to the air gap AG described above is similarly provided for the conductive pillar WP1 in a cross-section not shown.

### 1.2. Manufacturing Method

FIGS. 5, 7, 9, 11, 13, 15, 17, 19, 21, 23, 25, 27, 29, 31, 33, 35, 37, 39, 41, 43, 45, 47, 49, 51, 53, 55, and 57 are plan views showing an example of a planar layout of the memory device during manufacture according to the embodiment. FIGS. 6, 8, 10, 12, 14, 16, 18, 20, 22, 24, 26, 28, 30, 32, 34, 36, 38, 40, 42, 44, 46, 48, 50, 52, 54, 56, and 58 are cross-sectional views showing an example of a cross-sectional structure of the memory device during manufacture according to the embodiment. The planar layouts shown in FIGS. 5, 7, 9, 11, 13, 15, 17, 19, 21, 23, 25, 27, 29, 31, 33, 35, 37, 39, 41, 43, 45, 47, 49, 51, 53, 55, and 57 correspond to an upper portion of the plane shown in FIG. 3. The cross-sectional views shown in FIGS. 6, 8, 10, 12, 14, 16, 18, 20, 22, 24, 26, 28, 30, 32, 34, 36, 38, 40, 42, 44, 46, 48, 50, 52, 54, 56, and 58 correspond to cross-sections taken at the same position as the line IV-IV shown in FIG. 3 in the planar layouts shown in FIGS. 5, 7, 9, 11, 13, 15, 17, 19, 21, 23, 25, 27, 29, 31, 33, 35, 37, 39, 41, 43, 45, 47, 49, 51, 53, 55, and 57.

First, as shown in FIGS. 5 and 6, a stacked structure is formed on an upper surface of the substrate 20. Specifically, sacrificial layers 51 and 52 are stacked in this order on the upper surface of the substrate 20. Subsequently, sacrificial layers 53 and 52 are repeatedly stacked in this order on an upper surface of the sacrificial layer 52. The sacrificial layer 53 is further provided on an upper surface of the uppermost sacrificial layer 52. In the stacked structure, positions at which the sacrificial layers 52 are provided are layers that each correspond to the layer unit LU. The sacrificial layers 51 and 53 include, for example, silicon nitride. The sacrificial layer 52 includes, for example, silicon oxide.

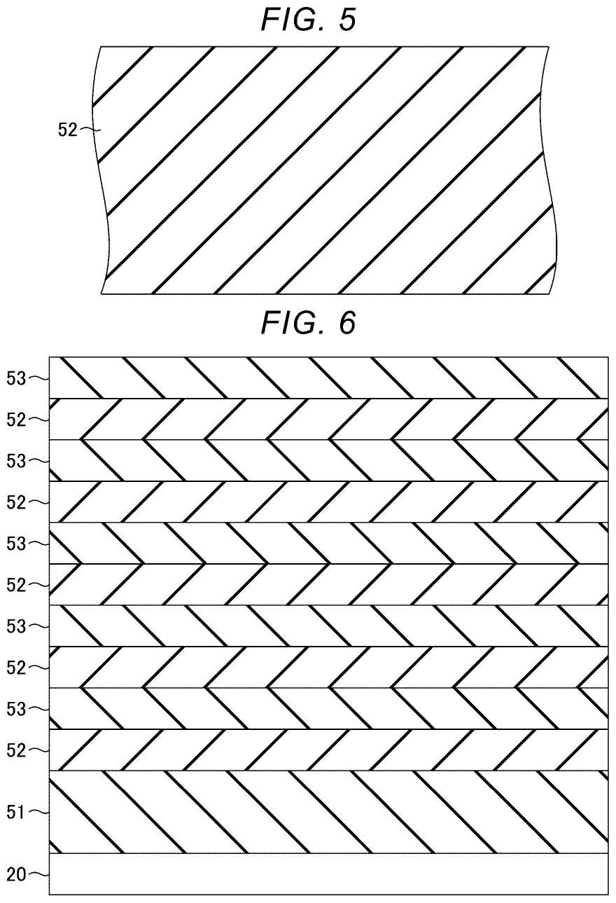

Next, as shown in FIGS. 7 and 8, a plurality of holes H1 are provided in a region of the stacked structure at which the plurality of conductive pillars WP1, WP2, and DP, and the conductive pillar SP (not shown) are to be provided. Specifically, the plurality of holes H1 are provided in a staggered arrangement arranged in the P direction and the Q direction when viewed in the Z direction. Each of the plurality of holes H1 penetrates the sacrificial layers 51, 52, and 53. Each bottom portion of the plurality of holes H1 reaches the substrate 20.

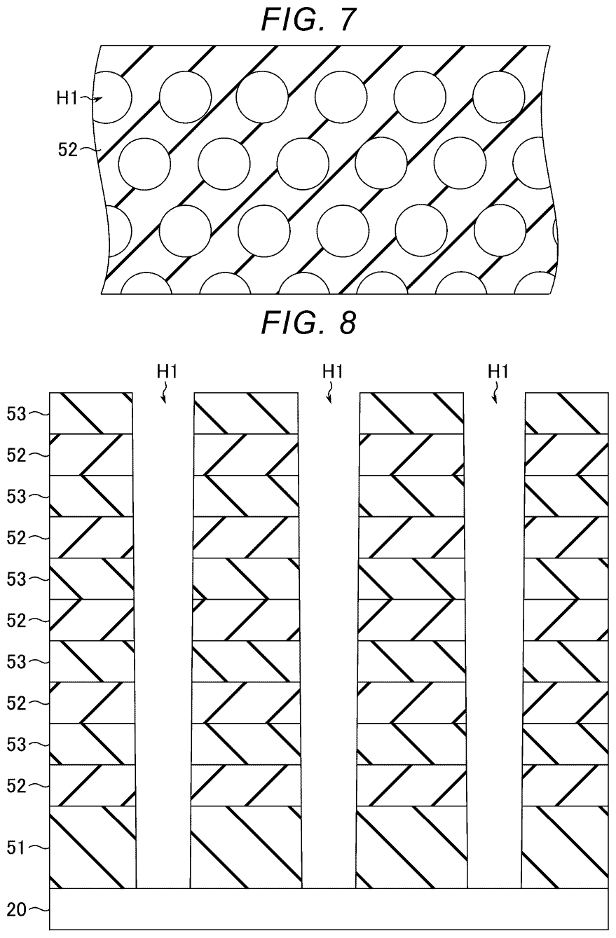

Next, as shown in FIGS. 9 and 10, each of the plurality of holes H1 is filled with a stop film 61 and a sacrificial film 62. The stop film 61 includes, for example, amorphous silicon. The sacrificial film 62 includes, for example, silicon oxide. A portion of the stop film 61 and the sacrificial film 62 provided above the hole H1 (that is, an upper surface of the sacrificial layer 53) is removed by, for example, chemical mechanical polishing (CMP). Then, a sacrificial layer 54 is provided on upper surfaces of the sacrificial layer 53 and the stop film 61 and the sacrificial film 62 filling the hole H1. The sacrificial layer 54 includes, for example, silicon nitride.

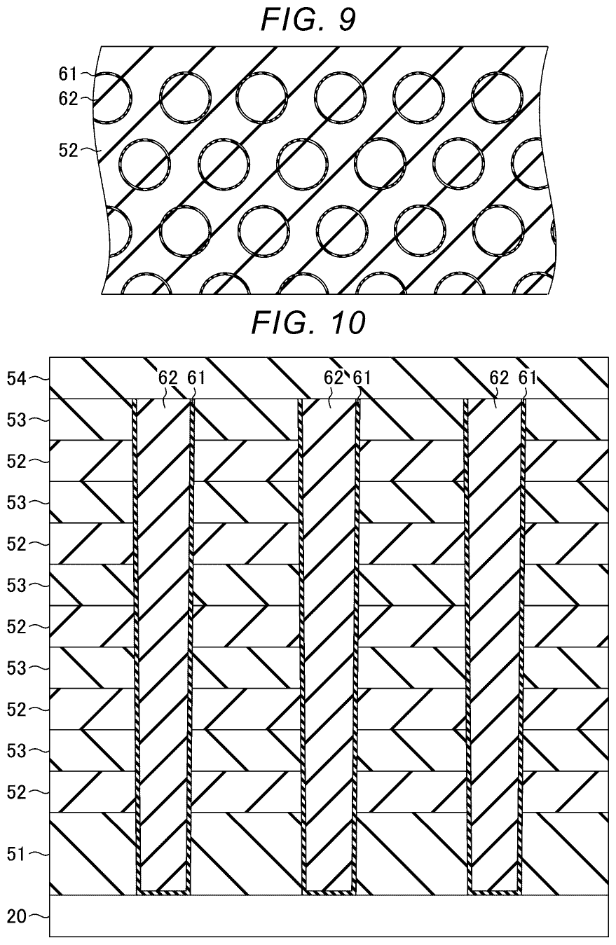

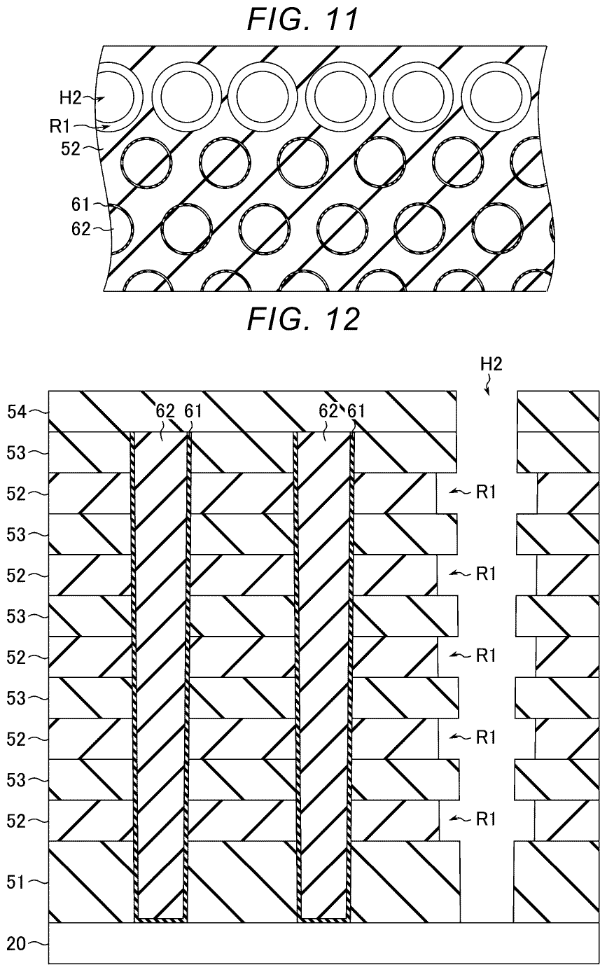

Next, as shown in FIGS. 11 and 12, a plurality of holes H2 are provided in a region of the stacked structure at which the plurality of conductive pillars DP and the conductive pillar SP (not shown) are to be provided. Specifically, the sacrificial film 62 and the stop film 61 provided in the region at which the plurality of conductive pillars DP and SP are to be provided are removed. As a result, the sacrificial layer 52 is exposed in each layer inside each of the plurality of holes H2. Then, the sacrificial layer 52 exposed in each layer is partially removed via the plurality of holes H2. As a result, a groove R1 concentrically extending from a center of the plurality of holes H2 is formed in each layer.

Next, as shown in FIGS. 13 and 14, each of the grooves R1 and the plurality of holes H2 in each layer is filled with a stop film 63 and a sacrificial film 64. The stop film 63 includes, for example, silicon nitride. The sacrificial film 64 includes, for example, silicon oxide. A portion of the sacrificial film 64 provided above the hole H2 (that is, an upper surface of the sacrificial layer 54) is removed by, for example, etch-back.

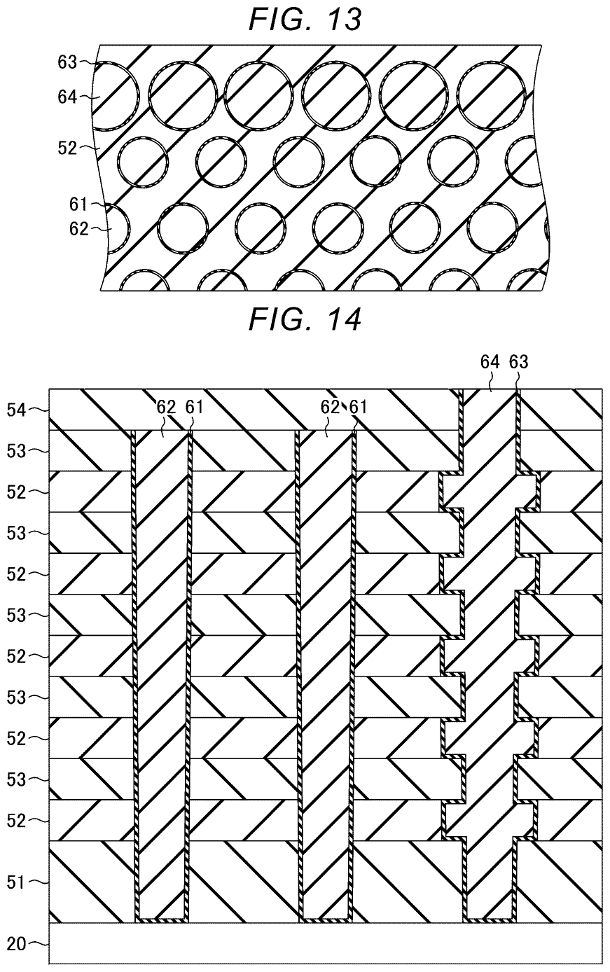

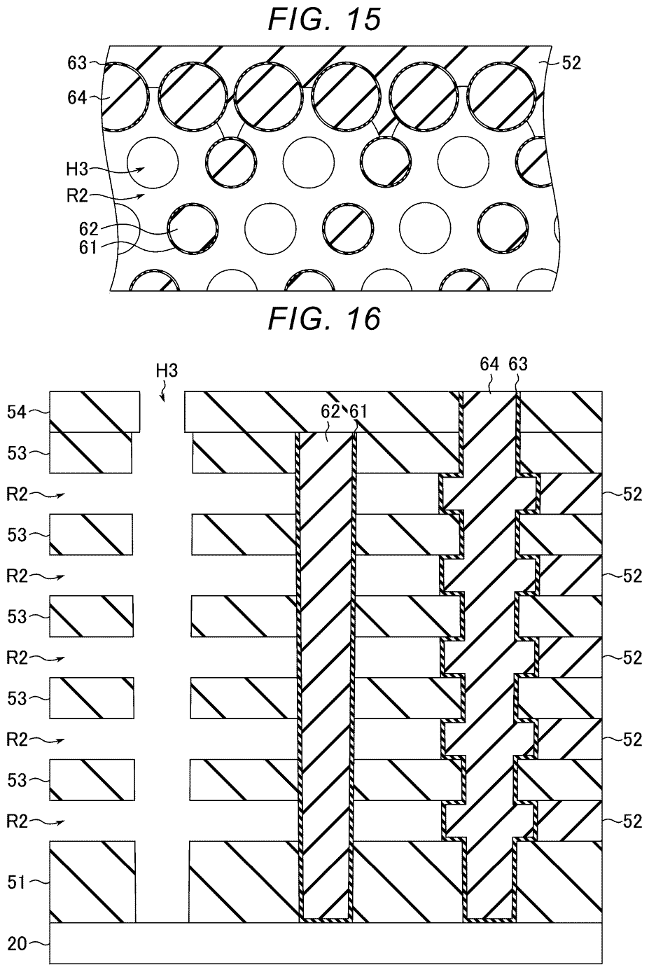

Next, as shown in FIGS. 15 and 16, a plurality of holes H3 are provided in a region of the stacked structure at which the plurality of conductive pillars WP1 are to be provided. Specifically, the sacrificial film 62 and the stop film 61 provided in the region at which the plurality of conductive pillars WP1 are to be provided are removed. As a result, the sacrificial layer 52 is exposed in each layer inside each of the plurality of holes H3. Then, the sacrificial layer 52 exposed in each layer is partially removed via the plurality of holes H3. As a result, a groove R2 concentrically extending from a center of the plurality of holes H3 is formed in each layer. A plurality of grooves R2 formed in each layer are connected. That is, in the grooves R2 in each layer, the stop film 61 corresponding to all the conductive pillars WP2 except for the conductive pillars WP2 adjacent to the conductive pillar DP or SP is fully exposed. In the grooves R2 in each layer, the stop film 61 corresponding to the conductive pillars WP2 adjacent to the conductive pillar DP or SP is exposed except for a portion facing the conductive pillar DP or SP. In the grooves R2 in each layer, the stop film 63 corresponding to the conductive pillars DP and SP is also partially exposed.

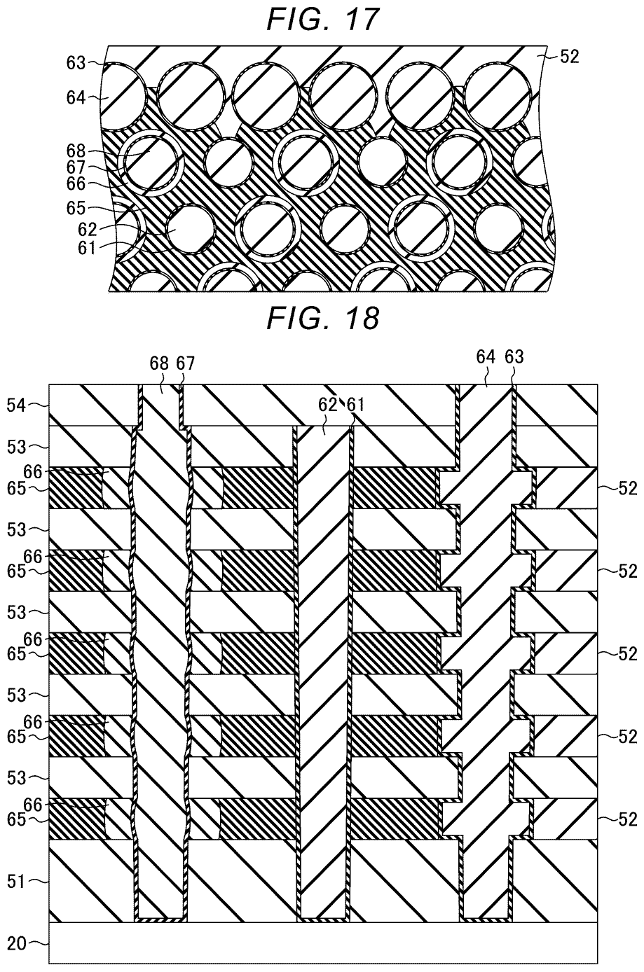

Next, as shown in FIGS. 17 and 18, the grooves R2 in each layer are filled with sacrificial films 65 and 66. The sacrificial film 65 includes, for example, amorphous silicon. The sacrificial film 66 includes, for example, silicon oxide. Then, each of the plurality of holes H3 is filled with a stop film 67 and a sacrificial film 68. The stop film 67 includes, for example, silicon nitride. The sacrificial film 68 includes, for example, silicon oxide. A portion of the sacrificial film 68 provided above the hole H3 (that is, the upper surface of the sacrificial layer 54) is removed by, for example, etch-back.

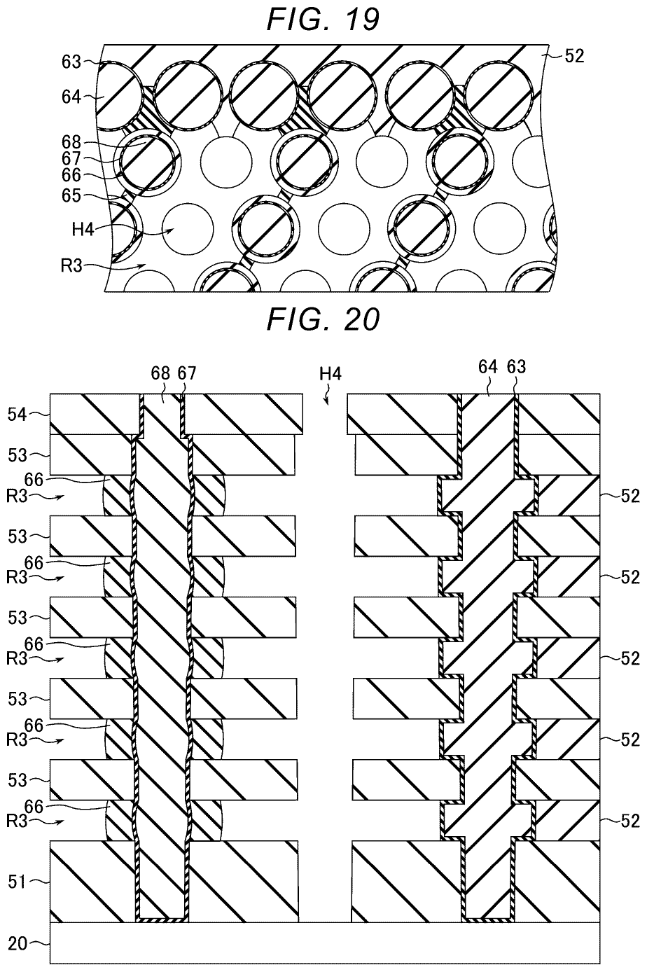

Next, as shown in FIGS. 19 and 20, a plurality of holes H4 are provided in a region of the stacked structure at which the plurality of conductive pillars WP2 are to be provided. Specifically, the sacrificial film 62 and the stop film 61 provided in the region at which the plurality of conductive pillars WP2 are to be provided are removed. As a result, the sacrificial film 65 is exposed in each layer inside each of the plurality of holes H4. Then, the sacrificial film 65 exposed in each layer is partially removed via the plurality of holes H4. As a result, a groove R3 concentrically extending from a center of the plurality of holes H4 is formed in each layer. Among the plurality of grooves R3 formed in each layer, a plurality of grooves R3 each formed via the plurality of holes H4 arranged in the P direction are connected. Meanwhile, the plurality of grooves R3 each formed via the plurality of holes H4 arranged in the X direction are maintained in a separated state by the sacrificial film 66 corresponding to the conductive pillar WP1 and the sacrificial film 65 remaining when forming the groove R3. In the grooves R3 in each layer, an exposed portion of the sacrificial film 66 corresponding to the conductive pillar WP1 is divided into two portions by the remaining sacrificial film 65. The two portions divided from the exposed portion of the sacrificial film 66 become portions corresponding to locations at which two memory stacked films corresponding to one conductive pillar WP1 are formed. In the grooves R3 in each layer, the stop film 63 corresponding to the conductive pillars DP and SP is also partially exposed.

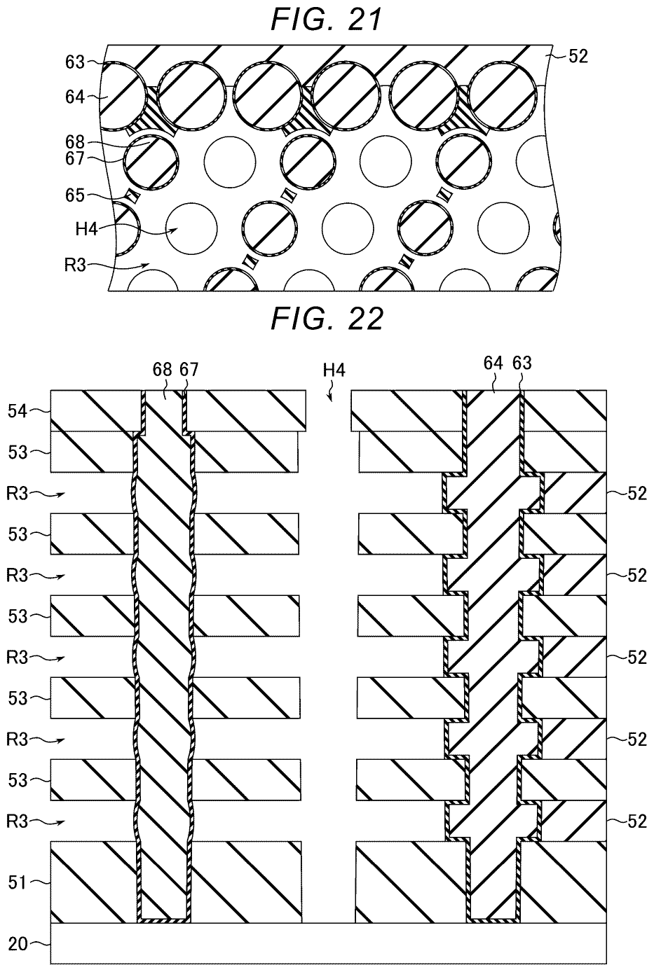

Next, as shown in FIGS. 21 and 22, the sacrificial film 66 corresponding to the conductive pillar WP1 is removed in each layer via the plurality of grooves R3. As a result, the plurality of grooves R3 previously separated in each layer are connected via a space formed by removing the sacrificial film 66.

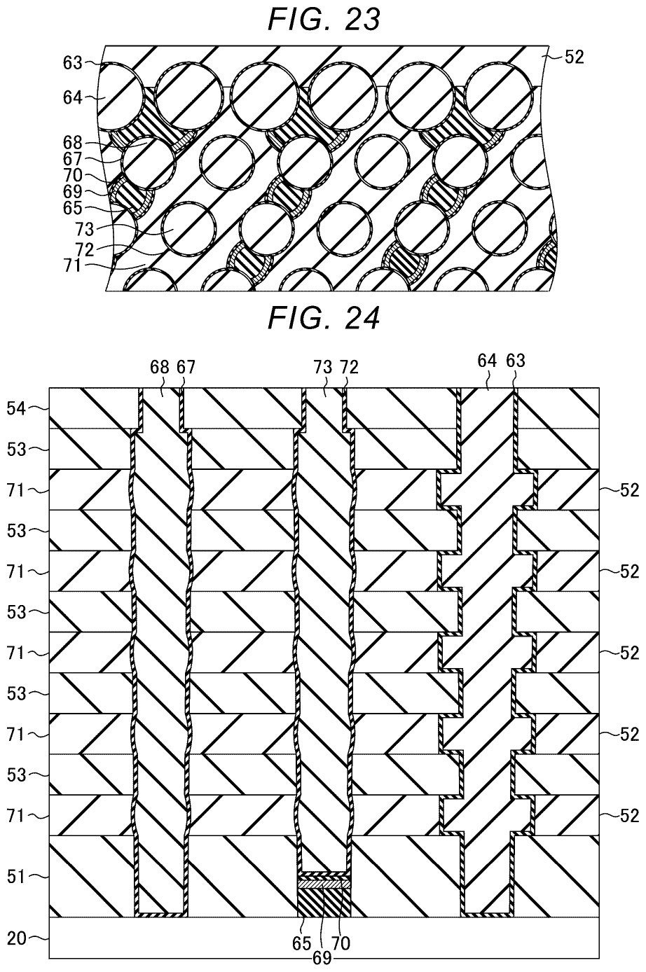

Next, as shown in FIGS. 23 and 24, the sacrificial film 65 is selectively grown via the grooves R3 in each layer. As a result, the sacrificial film 65 is in contact with the stop film 67 corresponding to the two conductive pillars WP1 sandwiching the sacrificial film 65 in the P direction. Accordingly, the grooves R3 in each layer are divided into a plurality of portions by the stop film 67 corresponding to the conductive pillar WP1 and the sacrificial film 65. By the selective growth treatment, the sacrificial film 65 is also provided on the substrate 20 exposed at a bottom portion of the hole H4.

Then, in each layer, the semiconductor film 69 is selectively grown on the sacrificial film 65 via the plurality of grooves R3. Then, the insulator film 70 is provided on the semiconductor film 69 by oxidizing a surface of the semiconductor film 69. The semiconductor film 69 and the insulator film 70 are also stacked on the sacrificial film 65 exposed at the bottom portion of the hole H4 by the selective growth treatment and the oxidation treatment. The semiconductor film 69 includes, for example, amorphous silicon. The insulator film 70 includes, for example, silicon oxide.

After the oxidation treatment of the semiconductor film 69 via the groove R3, the grooves R3 in each layer is filled with a sacrificial film 71. The sacrificial film 71 includes, for example, silicon oxide. Then, each of the plurality of holes H4 is filled with a stop film 72 and a sacrificial film 73. The stop film 72 includes, for example, silicon nitride. The sacrificial film 73 includes, for example, silicon oxide. A portion of the sacrificial film 73 provided above the hole H4 (that is, the upper surface of the sacrificial layer 54) is removed by, for example, etch-back.

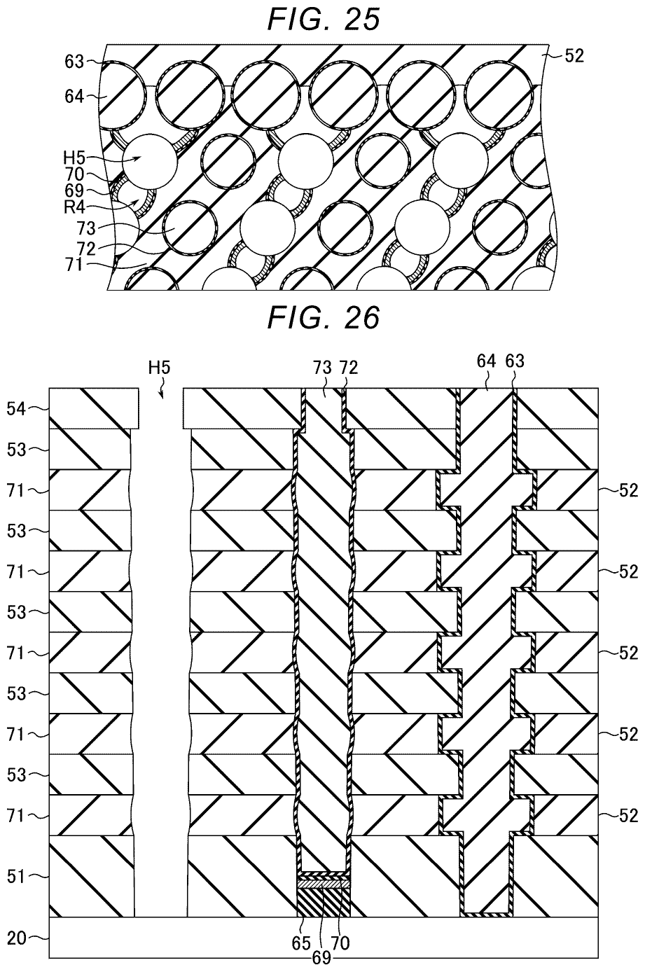

Next, as shown in FIGS. 25 and 26, a plurality of holes H5 are provided in a region of the stacked structure at which the plurality of conductive pillars WP1 are to be provided. Specifically, the sacrificial film 68 and the stop film 67 provided in the region at which the plurality of conductive pillars WP1 are to be provided are removed. As a result, the sacrificial film 65 is exposed in each layer inside each of the plurality of holes H5. Then, the sacrificial film 65 exposed in each layer is removed via the plurality of holes H5. As a result, in each layer, a groove R4 is formed in a space formed by removing the sacrificial film 65. The plurality of holes H5 arranged in the P direction are connected via a plurality of grooves R4 formed in each layer. Meanwhile, the plurality of holes H5 arranged in the X direction are maintained in a separated state by the sacrificial film 71 or the like.

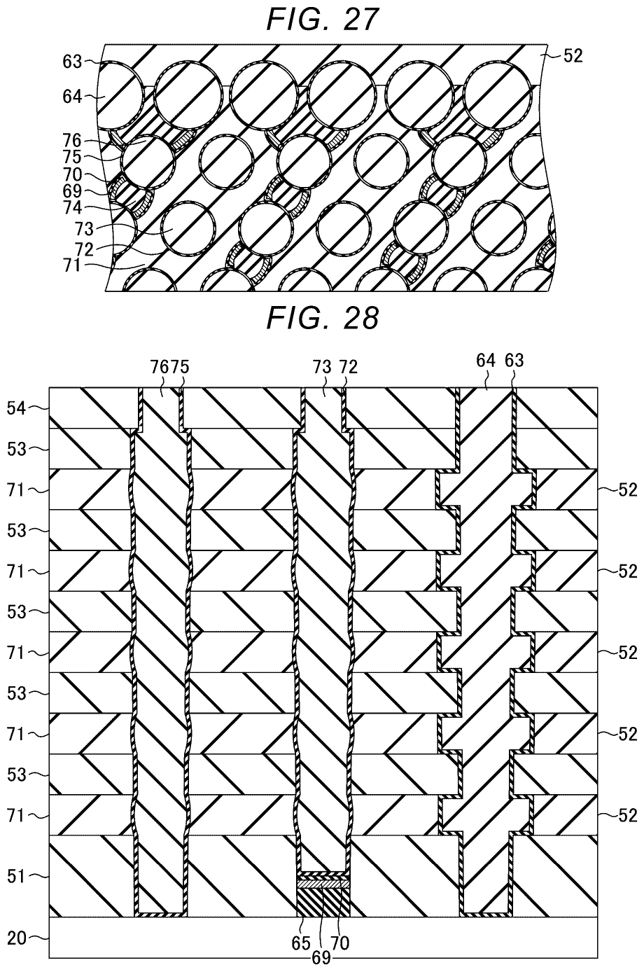

Next, as shown in FIGS. 27 and 28, the grooves R4 in each layer are filled with a sacrificial film 74. The sacrificial film 74 includes, for example, silicon nitride. Then, a surface of the semiconductor film 69 exposed in each layer inside the plurality of holes H5 is oxidized.

After the oxidation treatment of the semiconductor film 69 via the holes H5, each of the plurality of holes H5 is filled with a stop film 75 and a sacrificial film 76. The stop film 75 includes, for example, amorphous silicon. The sacrificial film 76 includes, for example, silicon oxide. A portion of the stop film 75 and the sacrificial film 76 provided above the hole H5 (that is, the upper surface of the sacrificial layer 54) is removed by, for example, etch-back.

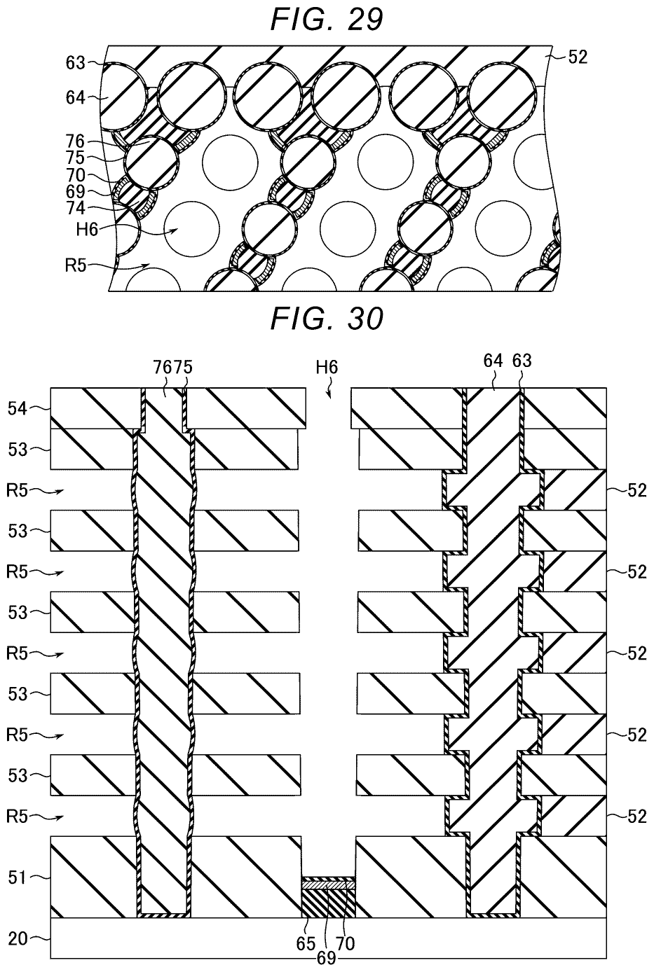

Next, as shown in FIGS. 29 and 30, a plurality of holes H6 are provided in a region of the stacked structure at which the plurality of conductive pillars WP2 are to be provided. Specifically, the sacrificial film 73 and the stop film 72 provided in the region at which the plurality of conductive pillars WP2 are to be provided are removed. As a result, the sacrificial film 71 is exposed in each layer inside each of the plurality of holes H6. Then, the sacrificial film 71 exposed in each layer is removed via the plurality of holes H6. As a result, in each layer, a groove R5 is formed in a space formed by removing the sacrificial film 71. The plurality of holes H6 arranged in the P direction are connected via a plurality of grooves R5 formed in each layer. Meanwhile, the plurality of holes H6 arranged in the X direction are maintained in a separated state by the insulator film 70, the stop film 75, or the like.

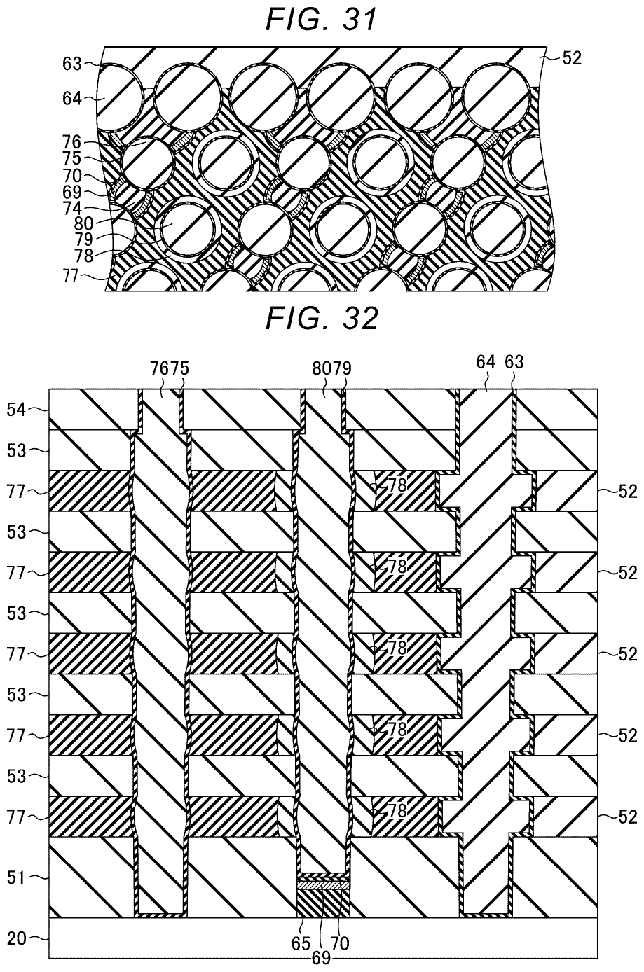

Next, as shown in FIGS. 31 and 32, the grooves R5 in each layer are filled with sacrificial films 77 and 78. The sacrificial film 77 includes, for example, amorphous silicon. The sacrificial film 78 includes, for example, silicon oxide. Then, each of the plurality of holes H6 is filled with a stop film 79 and a sacrificial film 80. The stop film 79 includes, for example, silicon nitride. The sacrificial film 80 includes, for example, silicon oxide. A portion of the sacrificial film 80 provided above the hole H6 (that is, the upper surface of the sacrificial layer 54) is removed by, for example, etch-back.

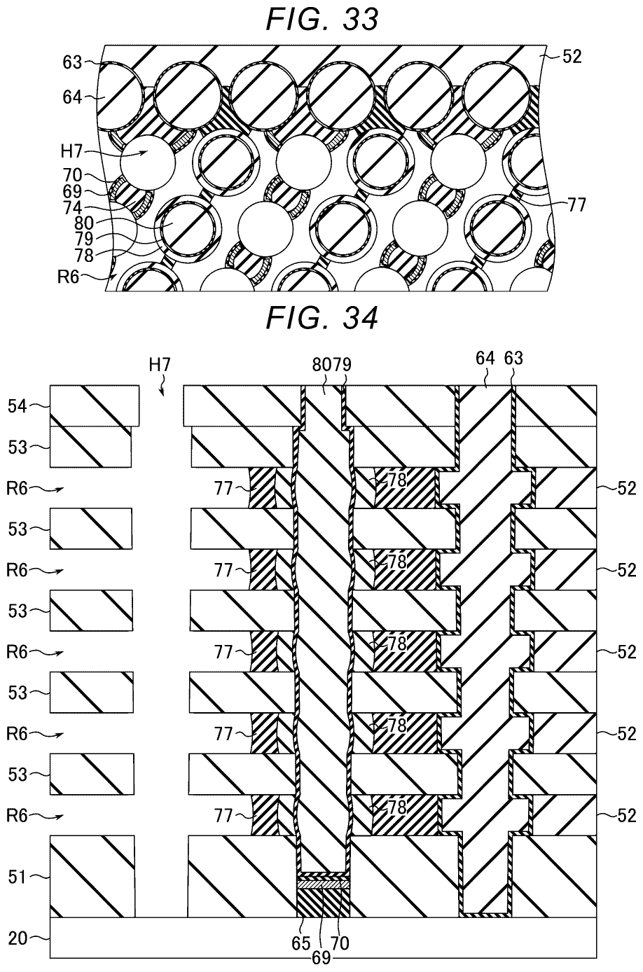

Next, as shown in FIGS. 33 and 34, a plurality of holes H7 are provided in a region of the stacked structure at which the plurality of conductive pillars WP1 are to be provided. Specifically, the sacrificial film 76 provided in the region at which the plurality of conductive pillars WP1 are to be provided is removed. A portion of the stop film 75 and the sacrificial film 77 in each layer are removed via each of the plurality of holes H7. Since the stop film 75 and the sacrificial film 77 include the same material (for example, amorphous silicon), the films are simultaneously removed by a single etching process. As a result, a groove R6 concentrically extending from a center of the plurality of holes H7 is formed in each layer. Among the plurality of grooves R6 formed in each layer, a plurality of grooves R6 each formed via the plurality of holes H7 arranged in the P direction are connected. Meanwhile, the plurality of grooves R6 each formed via the plurality of holes H7 arranged in the X direction are maintained in a separated state by the sacrificial film 78 corresponding to the conductive pillar WP2 and the sacrificial film 77 remaining when forming the groove R6. In the grooves R6 in each layer, an exposed portion of the sacrificial film 78 corresponding to the conductive pillar WP2 is divided into two portions by the remaining sacrificial film 77. The two portions divided from the exposed portion of the sacrificial film 77 become portions corresponding to locations at which two memory stacked films corresponding to one conductive pillar WP2 are formed. In the grooves R6 in each layer, the stop film 63 corresponding to the conductive pillars DP and SP is also partially exposed.

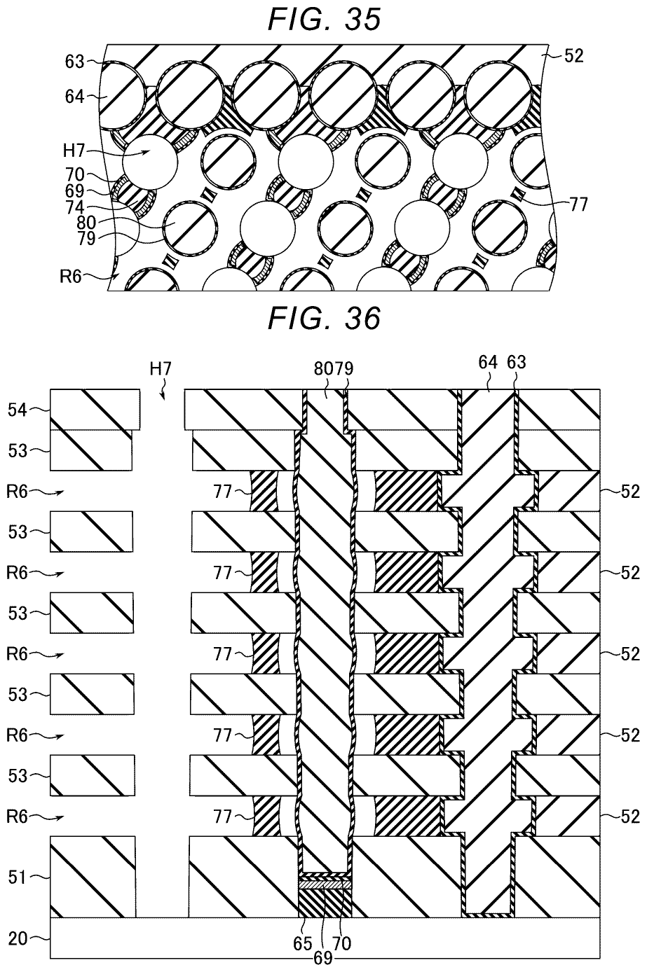

Next, as shown in FIGS. 35 and 36, the sacrificial film 78 corresponding to the conductive pillar WP2 is removed in each layer via the plurality of grooves R6. As a result, the plurality of grooves R6 previously separated in each layer are connected via a space formed by removing the sacrificial film 78.

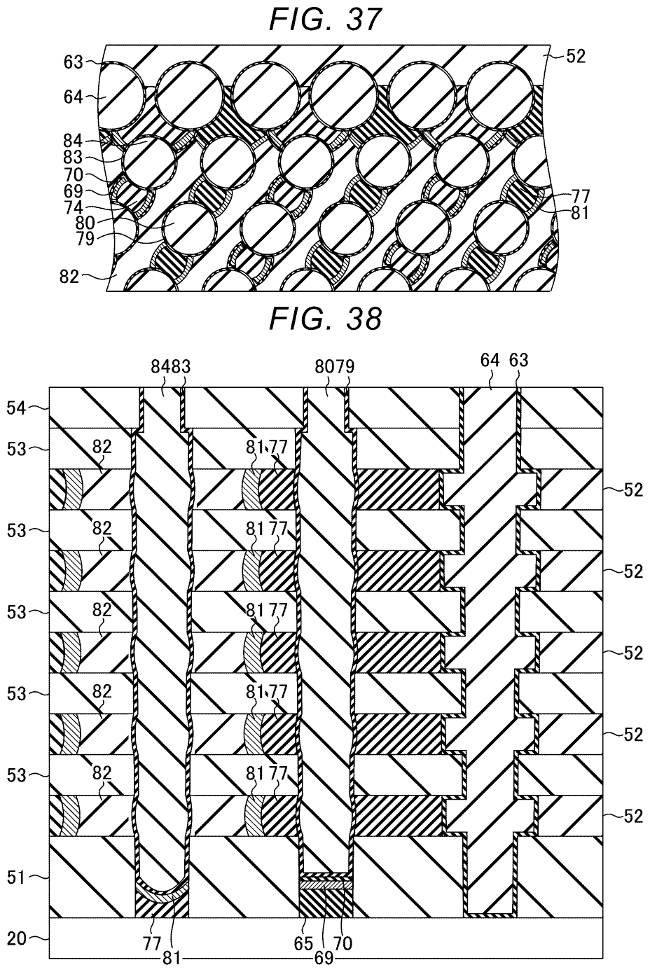

Next, as shown in FIGS. 37 and 38, the sacrificial film 77 is selectively grown via the grooves R6 in each layer. As a result, the sacrificial film 77 is in contact with the stop film 79 corresponding to the two conductive pillars WP2 sandwiching the sacrificial film 77 in the P direction. Accordingly, the grooves R6 in each layer are divided into a plurality of portions by the stop film 79 corresponding to the conductive pillar WP2 and the sacrificial film 77. By the selective growth treatment, the sacrificial film 77 is also provided on the substrate 20 exposed at a bottom portion of the hole H7.

Then, in each layer, the semiconductor film 81 is selectively grown on the sacrificial film 77 via the plurality of grooves R6. The semiconductor film 81 is also stacked on the sacrificial film 77 exposed at the bottom portion of the hole H7 by the selective growth treatment. The semiconductor film 81 includes, for example, amorphous silicon.

After the selective growth treatment of the sacrificial film 77 via the groove R6, the grooves R6 in each layer are filled with a sacrificial film 82. The sacrificial film 82 includes, for example, silicon oxide. Then, each of the plurality of holes H7 is filled with a stop film 83 and a sacrificial film 84. The stop film 83 includes, for example, amorphous silicon. The sacrificial film 84 includes, for example, silicon oxide. A portion of the stop film 83 and the sacrificial film 84 provided above the hole H7 (that is, the upper surface of the sacrificial layer 54) is removed by, for example, etch-back.

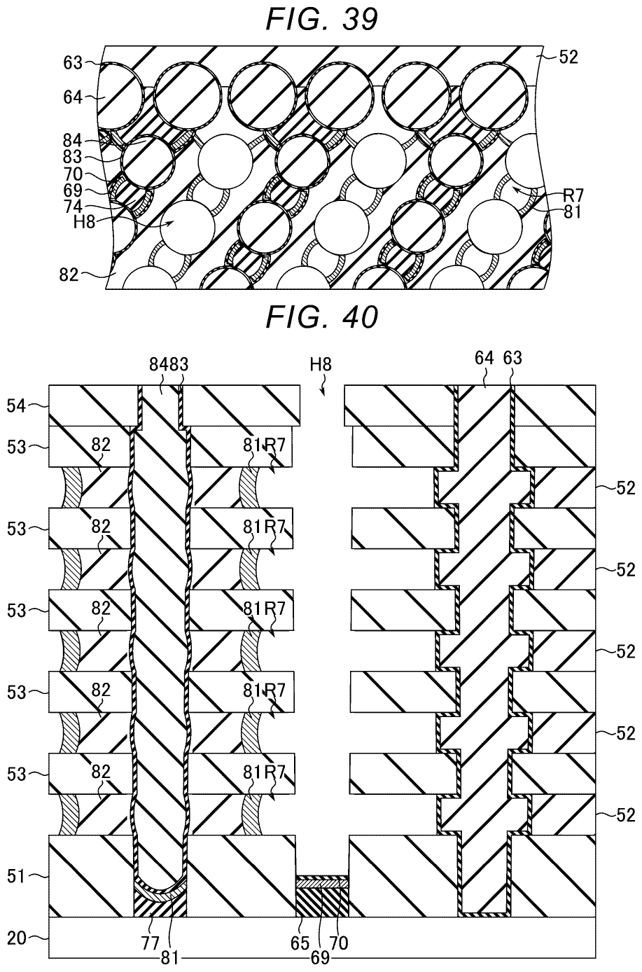

Next, as shown in FIGS. 39 and 40, a plurality of holes H8 are provided in a region of the stacked structure at which the plurality of conductive pillars WP2 are to be provided. Specifically, the sacrificial film 80 and the stop film 79 provided in the region at which the plurality of conductive pillars WP2 are to be provided are removed. As a result, the sacrificial film 77 is exposed in each layer inside each of the plurality of holes H8. Then, the sacrificial film 77 exposed in each layer is removed via the plurality of holes H8. As a result, in each layer, a groove R7 is formed in a space formed by removing the sacrificial film 77. The plurality of holes H8 arranged in the P direction are connected via a plurality of grooves R7 formed in each layer. Meanwhile, the plurality of holes H8 arranged in the X direction are maintained in a separated state by the sacrificial film 82 or the like.

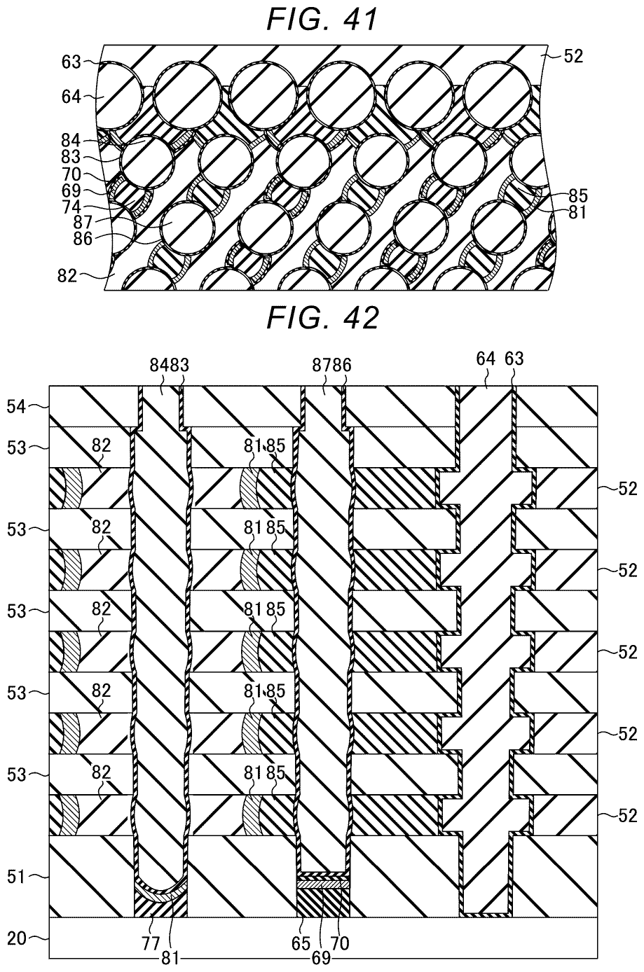

Next, as shown in FIGS. 41 and 42, the grooves R7 in each layer are filled with a sacrificial film 85. The sacrificial film 85 includes, for example, silicon nitride. Then, each of the plurality of holes H8 is filled with a stop film 86 and a sacrificial film 87. The stop film 86 includes, for example, amorphous silicon. The sacrificial film 87 includes, for example, silicon oxide. A portion of the stop film 86 and the sacrificial film 87 provided above the hole H8 (that is, the upper surface of the sacrificial layer 54) is removed by, for example, etch-back.

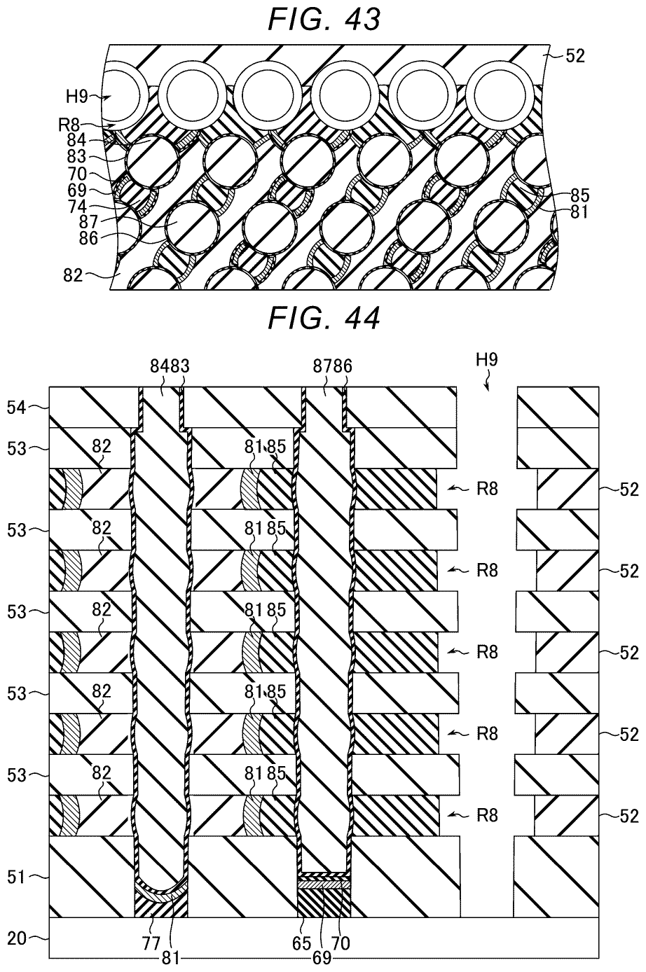

Next, as shown in FIGS. 43 and 44, a plurality of holes H9 are provided in a region of the stacked structure at which the plurality of conductive pillar DP and the conductive pillar SP (not shown) are to be provided. Specifically, the sacrificial film 64 and the stop film 63 provided in the region at which a plurality of conductive pillars DP and SP are to be provided are removed. As a result, the sacrificial layer 52 and the sacrificial film 85 are exposed in each layer inside each of the plurality of holes H9. In each layer, a groove R8 extending concentrically from a center of the plurality of holes H9 is formed.

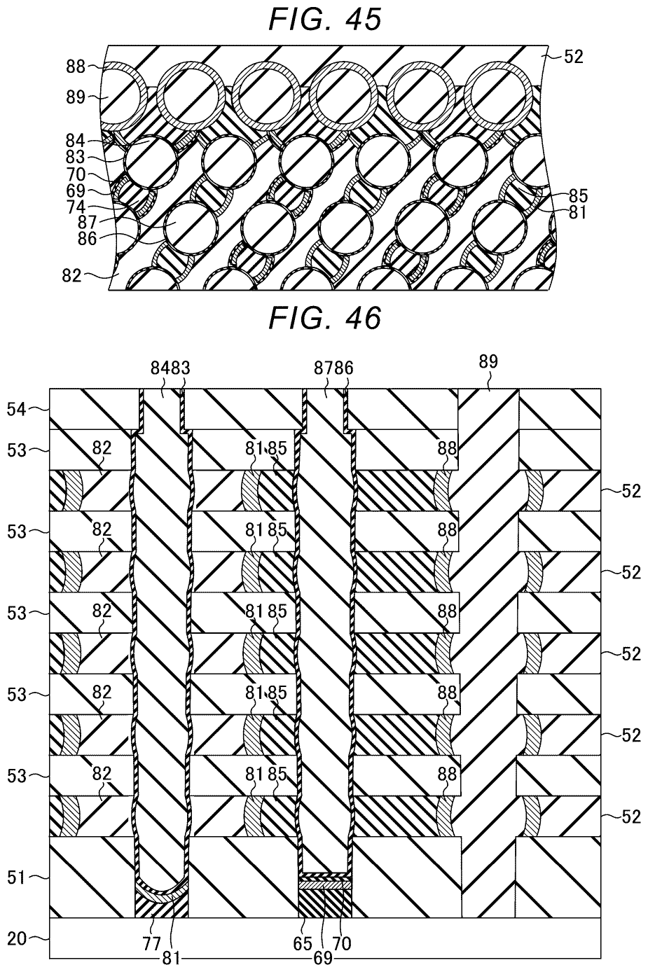

Next, as shown in FIGS. 45 and 46, the semiconductor film 88 is provided in the grooves R8 in each layer. The semiconductor film 88 corresponding to the conductive pillar DP is in contact with the semiconductor film 69 provided between the conductive pillars DP and WP1. Meanwhile, the semiconductor film 88 corresponding to the conductive pillar DP is not in contact with the semiconductor film 81 provided between the conductive pillars DP and WP2 due to the presence of the insulator film 70. Similarly, the semiconductor film 88 corresponding to the conductive pillar SP (not shown) is in contact with the semiconductor film 69 provided between the conductive pillars DP and WP1. Meanwhile, the semiconductor film 88 corresponding to the conductive pillar SP is not in contact with the semiconductor film 81 provided between the conductive pillars DP and WP2 due to the presence of the insulator film 70. The semiconductor film 88 includes, for example, amorphous silicon.

The grooves R8 in each layer are not completely filled by the semiconductor film 88. Each of the grooves R8 and the plurality of holes H9 in each layer is filled with a sacrificial film 89. The sacrificial film 89 includes, for example, silicon oxide. A portion of the sacrificial film 89 provided above the hole H9 (that is, the upper surface of the sacrificial layer 54) is removed by, for example, etch-back.

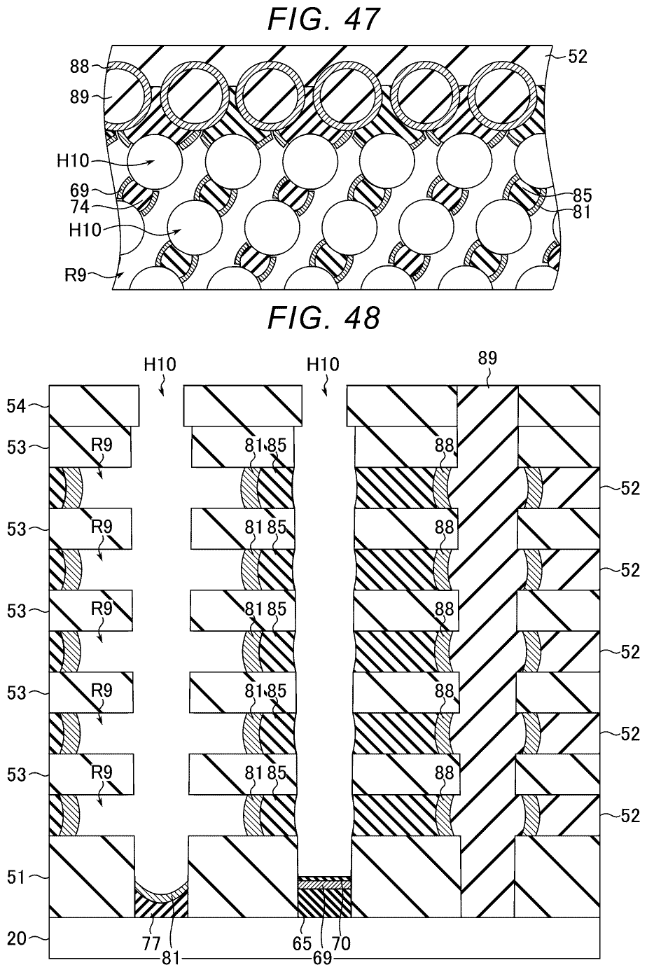

Next, as shown in FIGS. 47 and 48, a plurality of holes H10 are provided in a region of the stacked structure at which the plurality of conductive pillar WP1 and WP2 are to be provided. Specifically, the sacrificial film 84 and the stop film 83 provided in the region at which the plurality of conductive pillars WP1 are to be provided and the sacrificial film 87 and the stop film 86 provided in the region at which the plurality of conductive pillars WP2 are to be provided are removed. Since the sacrificial films 84 and 87 include the same material (for example, silicon oxide), the films are simultaneously removed by a single etching process. Since the stop films 83 and 86 include the same material (for example, amorphous silicon), the films are simultaneously removed by a single etching process. As a result, the semiconductor film 81, the sacrificial film 82, and the like are exposed in each layer inside each of the plurality of holes H10. The semiconductor film 69 is not exposed at this stage since the semiconductor film 69 is covered with the insulator film 70.

The insulator film 70 and the sacrificial film 82 are removed via each of the plurality of holes H10. Since the insulator film 70 and the sacrificial film 82 include the same material (for example, silicon oxide), the films are simultaneously removed by a single etching process. As a result, in each layer, a groove R9 is formed in a space formed by removing the insulator film 70 and the sacrificial film 82. In the groove R9, the semiconductor film 69 is further exposed. All of the holes H10 are connected via a plurality of grooves R9 formed in each layer.

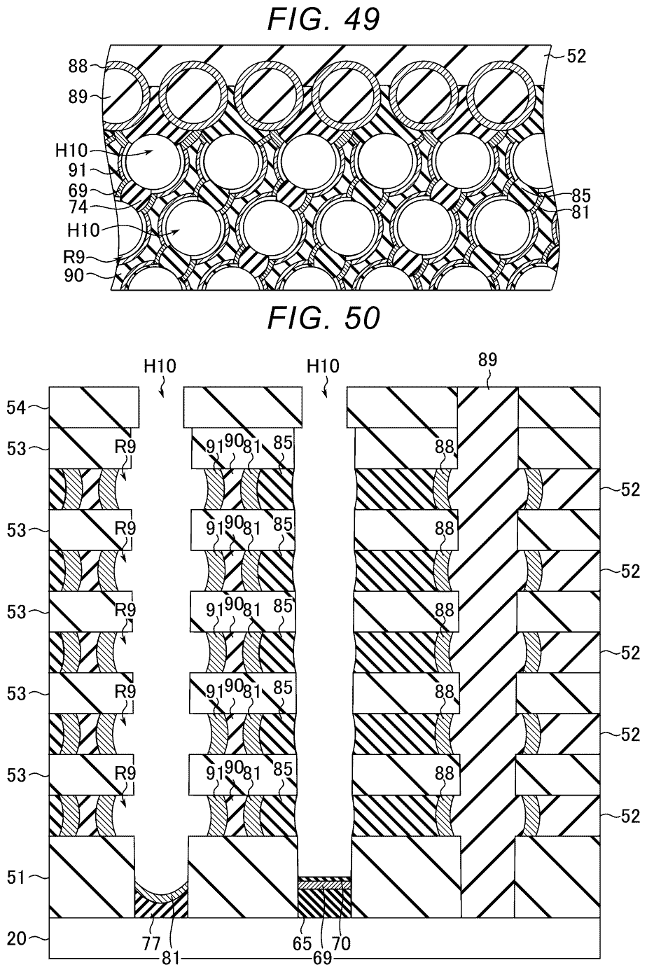

Next, as shown in FIGS. 49 and 50, the semiconductor films 69 and 81 are selectively grown via the plurality of grooves R9 in each layer. As a result, the semiconductor film 88 corresponding to the conductive pillar DP is in contact with the semiconductor film 81 provided between the conductive pillars DP and WP2 directly or via the semiconductor film 69 provided between the conductive pillars DP and WP1. Similarly, the semiconductor film 88 corresponding to the conductive pillar SP (not shown) is in contact with the semiconductor film 81 provided between the conductive pillar SP and WP2 directly or via the semiconductor film 69 provided between the conductive pillars SP and WP1.

Then, the insulator film 90 and the semiconductor film 91 are provided in this order in the grooves R9 in each layer. The semiconductor film 91 includes, for example, amorphous silicon. The grooves R9 in each layer are not completely filled by the semiconductor film 91. As a result, each of two semiconductor films 91 provided separately from each other is provided around the hole H10 corresponding to the conductive pillar WP1 and connects between the semiconductor films 69 arranged in the P direction. Each of the two semiconductor films 91 separated from each other is provided around the hole H10 corresponding to the conductive pillar WP2 and connects between the semiconductor films 81 arranged in the P direction. Accordingly, two independent conductive paths are provided between the semiconductor film 88 corresponding to the conductive pillar DP and the semiconductor film 88 corresponding to the conductive pillar SP.

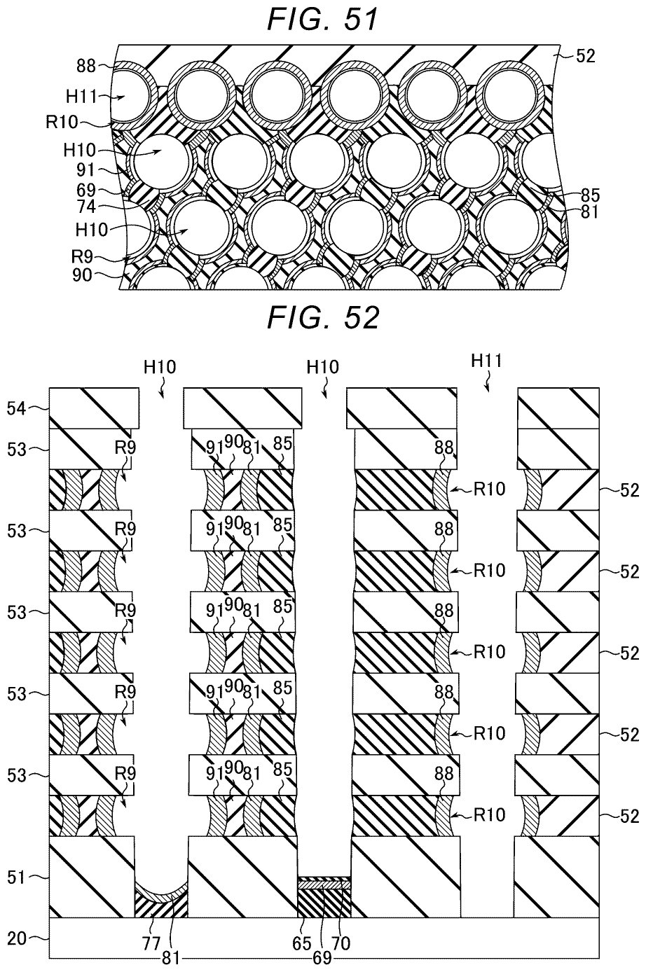

Next, as shown in FIGS. 51 and 52, a plurality of holes H11 are provided in the region of the stacked structure at which the plurality of conductive pillars DP and the conductive pillar SP (not shown) are to be provided. Specifically, the sacrificial film 89 provided in the region at which the plurality of conductive pillars DP and SP are to be provided is removed. As a result, a groove R10 is formed in each layer inside each of the plurality of holes H11. In the groove R10, the semiconductor film 88 is exposed.

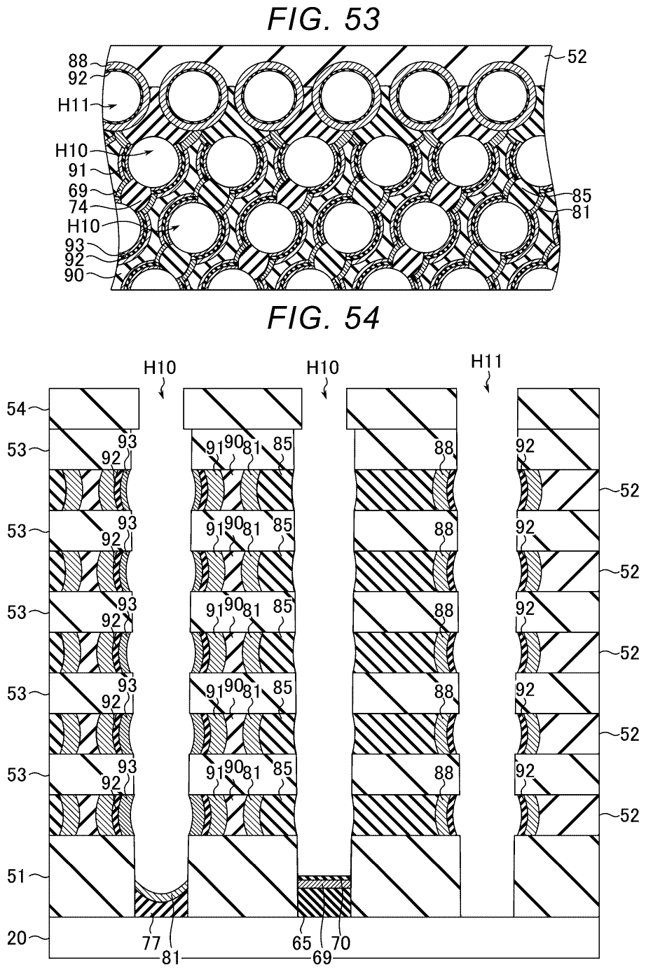

Next, as shown in FIGS. 53 and 54, the insulator film 92 is provided in the grooves R9 and R10 in each layer. As a result, the grooves R10 in each layer are filled with the insulator film 92. The grooves R9 in each layer are not completely filled by the insulator film 92.

Then, the semiconductor film 93 is provided in each of the grooves R9 and the plurality of holes H11 in each layer. As a result, the grooves R9 in each layer are filled with the semiconductor film 93. For example, the semiconductor films 93 filling the grooves R9 in each layer are separated from each other in the Z direction by, for example, etch-back. As described above, the grooves R10 in the hole H11 are filled with the insulator film 92. Therefore, the semiconductor film 88 formed in the hole H11 is completely removed by the etch-back treatment. The semiconductor film 93 includes, for example, amorphous silicon.

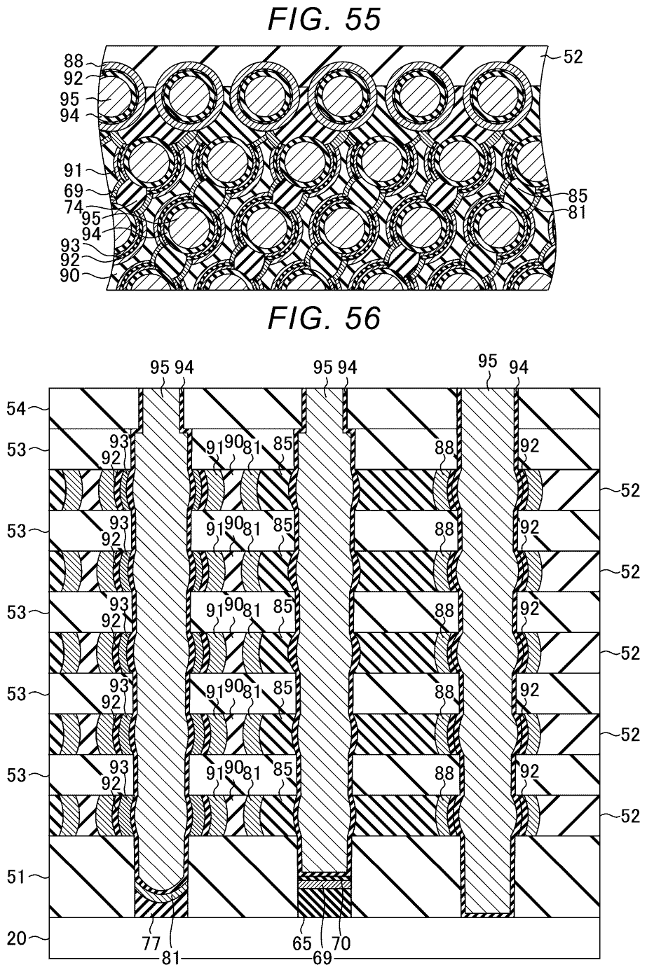

Next, as shown in FIGS. 55 and 56, each of the plurality of holes H10 and H11 is filled with the insulator film 94 and the conductor film 95. A portion of the insulator film 94 and the conductor film 95 provided above the holes H10 and H11 (that is, the upper surface of the sacrificial layer 54) is removed by, for example, etch-back.

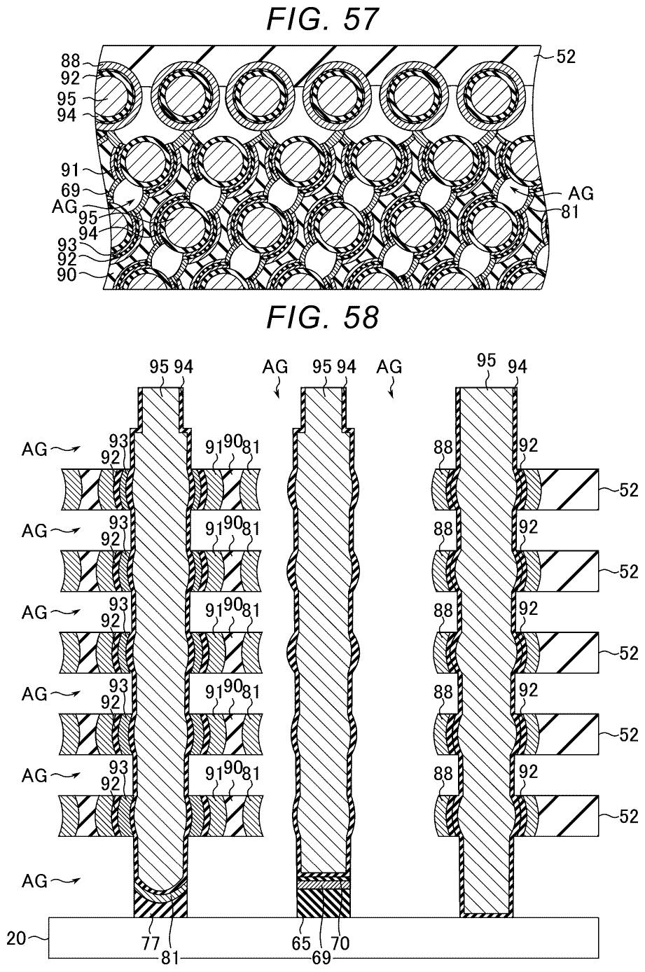

Next, as shown in FIGS. 57 and 58, the sacrificial films 74 and 85 and the sacrificial layers 53 and 54 are removed. As a result, the air gap AG is formed.

Then, a process of replacing the sacrificial layer 52 remaining on the conductive pillar DP side with the bit line BL and a process of replacing the sacrificial layer 52 remaining on the conductive pillar SP side with the source line SL are performed. By a heat treatment, a process of crystallizing amorphous silicon into polysilicon is performed. Then, the contact WV and the word line WL are formed. Through the above processes, the memory device 3 is formed.

### 2. Effects of Embodiment

According to the embodiment, each of the conductive pillars DP, WP1, and WP2 is surrounded by the semiconductor films 88, 91, and 91. The channel film DCH corresponding to the conductive pillar DP, the channel film WCH corresponding to the conductive pillar WP1 adjacent to the conductive pillar DP in the P direction, and the channel film WCH corresponding to the conductive pillar WP2 adjacent to the conductive pillar DP in the Q direction are electrically connected by one current path film CPL that is a continuous film. As a result, two parallel current paths are formed from one conductive pillar DP. Therefore, two columns of series-connected memory cell transistors MT may be disposed in parallel with each other in one NAND string NS. Accordingly, an integration density of the memory device 3 can be improved.

In each layer, two charge storage films CSL are provided separately from each other and partially surround one conductive pillar WP1. In each layer, two charge storage films CSL are provided separately from each other and partially surround one conductive pillar WP2. Two current path films CPL provided between two adjacent conductive pillars WP1 are provided separately from each other and connected to different channel films WCH. Two current path films CPL provided between two adjacent conductive pillars WP2 are provided separately from each other and connected to different channel films WCH. As a result, two memory cell transistors MT can be configured in the same layer for one conductive pillar WP1 or WP2. Therefore, an integration density of the memory device 3 can be improved.

The air gap AG is provided between two adjacent conductive pillars WP1 or between two current path films CPL connecting between two adjacent conductive pillars WP2. As a result, interference between memory cell transistors MT provided in the same layer can be prevented.

The air gap AG is provided between adjacent layers. As a result, interference between a memory cell transistor MT provided in a certain layer and a memory cell transistor MT provided in an adjacent layer can be prevented.

### 3. Modifications and the Like

Various modifications may be applied to the embodiment described above.

For example, in the embodiment described above, an example of the NAND string NS with a linear shape extending in the P direction is described, but the embodiment is not limited thereto. For example, the NAND string NS may have a zigzag shape alternately extending in the P direction and the Q direction.

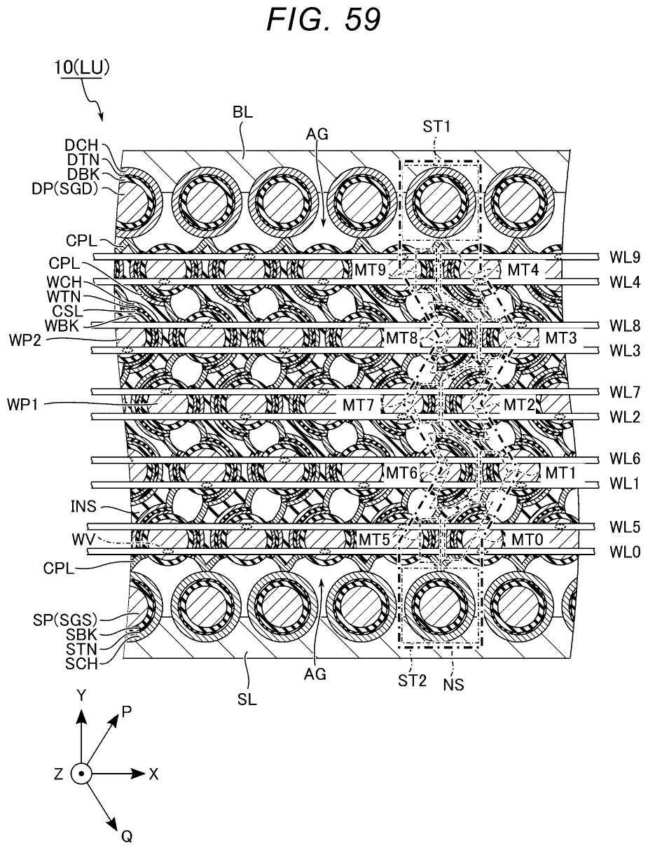

FIG. 59 is a plan view showing an example of a planar layout of a memory cell array in a memory device according to a modification. FIG. 59 corresponds to FIG. 3 in the embodiment.

As shown in FIG. 59, seven conductive pillars DP, WP1, WP2, WP1, WP2, WP1, and SP are arranged in the P direction in this order. Seven conductive pillars DP, WP2, WP1, WP2, WP1, WP2, and SP are arranged in this order in the P direction to be adjacent in the X direction to the seven conductive pillars DP, WP1, WP2, WP1, WP2, WP1, and SP arranged in this order in the P direction. A set including seven conductive pillars DP, WP1, WP2, WP1, WP2, WP1, and SP arranged in the P direction and a set including seven conductive pillars DP, WP2, WP1, WP2, WP1, WP2, and SP arranged in the P direction are alternately disposed in the X direction.

When viewed in the Q direction, the arrangement described above is also described as follows. That is, seven conductive pillars DP, WP1, WP1, WP2, WP2, WP1, and SP are arranged in this order in the Q direction. Seven conductive pillars DP, WP2, WP2, WP1, WP1, WP2, and SP are arranged in this order in the Q direction to be adjacent in the X direction to the seven conductive pillars DP, WP1, WP1, WP2, WP2, WP1, and SP arranged in this order in the Q direction. A set including seven conductive pillars DP, WP1, WP1, WP2, WP2, WP1, and SP arranged in the Q direction and a set including seven conductive pillars DP, WP2, WP2, WP1, WP1, WP2, and SP arranged in the Q direction are alternately disposed in the X direction.

According to the structure described above, between a pair of select transistors ST1 and ST2, the NAND string NS in which two sets each including five memory cell transistors MT alternately connected in series in the P direction and the Q direction are connected in parallel is implemented. Therefore, even in the modification, effects of improving an integration density of the memory device 3 and preventing intercell interference can be achieved as in the embodiment.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A memory device comprising:
a first conductive pillar, a second conductive pillar, and a third conductive pillar each extending in a first direction;
a first semiconductor film surrounding the first conductive pillar at a first position in the first direction;
a second semiconductor film partially surrounding the second conductive pillar at the first position;
a third semiconductor film partially surrounding the third conductive pillar at the first position;
a fourth semiconductor film in contact with each of the first semiconductor film, a first end of the second semiconductor film, and a first end of the third semiconductor film;
a first charge storage film provided between the second conductive pillar and the second semiconductor film; and
a second charge storage film provided between the third conductive pillar and the third semiconductor film.

2. The memory device according to claim 1, further comprising:
a fourth conductive pillar extending in the first direction;
a fifth semiconductor film partially surrounding the fourth conductive pillar at the first position;
a sixth semiconductor film in contact with each of a second end of the first semiconductor film and a first end of the fifth semiconductor film; and
a third charge storage film provided between the fourth conductive pillar and the fifth semiconductor film.

3. The memory device according to claim 2, further comprising:
a fifth conductive pillar extending in the first direction;
a seventh semiconductor film partially surrounding the fifth conductive pillar at the first position;
an eighth semiconductor film in contact with each of a second end of the second semiconductor film and a first end of the seventh semiconductor film; and
a fourth charge storage film provided between the fifth conductive pillar and the seventh semiconductor film.

4. The memory device according to claim 3, further comprising:
a first insulator film provided between the second semiconductor film and the third semiconductor film;
a second insulator film provided between the fifth semiconductor film and the seventh semiconductor film; and
a third insulator film provided between the sixth semiconductor film and the eighth semiconductor film.

5. The memory device according to claim 2, further comprising:
a sixth conductive pillar extending in the first direction;
a ninth semiconductor film surrounding the sixth conductive pillar at the first position;
a tenth semiconductor film separated from the second semiconductor film and partially surrounding the second conductive pillar at the first position;
an eleventh semiconductor film in contact with each of the ninth semiconductor film and a first end of the tenth semiconductor film; and
a fifth charge storage film provided between the second conductive pillar and the tenth semiconductor film.

6. The memory device according to claim 5, further comprising:
a twelfth semiconductor film separated from the fifth semiconductor film and partially surrounding the fourth conductive pillar at the first position;
a thirteenth semiconductor film in contact with each of a second end of the tenth semiconductor film and a first end of the twelfth semiconductor film; and
a sixth charge storage film provided between the fourth conductive pillar and the twelfth semiconductor film and separated from the third charge storage film.

7. The memory device according to claim 6, wherein an air gap is provided between the sixth semiconductor film and the thirteenth semiconductor film.

8. The memory device according to claim 6, further comprising:
a seventh conductive pillar extending in the first direction;
a fourteenth semiconductor film partially surrounding the seventh conductive pillar at the first position; and
a sixth charge storage film provided between the seventh conductive pillar and the twelfth semiconductor film, wherein
the eleventh semiconductor film is in contact with each of the ninth semiconductor film, a first end of the tenth semiconductor film, and a first end of the fourteenth semiconductor film.

9. The memory device according to claim 1, further comprising:
a fifteenth semiconductor film surrounding the first conductive pillar at a second position different from the first position in the first direction;
a sixteenth semiconductor film partially surrounding the second conductive pillar at the second position;
a seventeenth semiconductor film partially surrounding the third conductive pillar at the second position;
an eighteenth semiconductor film in contact with each of the fifteenth semiconductor film, a first end of the sixteenth semiconductor film, and a first end of the seventeenth semiconductor film;
a seventh charge storage film provided between the second conductive pillar and the sixteenth semiconductor film; and
an eighth charge storage film provided between the third conductive pillar and the seventeenth semiconductor film.

10. The memory device according to claim 9, wherein an air gap is provided between the first position and the second position.

11. The memory device according to claim 1, wherein
the first conductive pillar and the second conductive pillar are arranged in a second direction in a plane intersecting the first direction, and
the first conductive pillar and the third conductive pillar are arranged in a third direction intersecting the second direction in the plane.

12. The memory device according to claim 3, wherein
the first conductive pillar, the second conductive pillar, and the fourth conductive pillar are arranged in the second direction in a plane intersecting the first direction, and
the first conductive pillar, the third conductive pillar, and the fifth conductive pillar are arranged in a third direction intersecting the second direction in the plane.

13. The memory device according to claim 3, wherein
the first conductive pillar and the second conductive pillar are arranged in a second direction in a plane intersecting the first direction,
the second conductive pillar and the fourth conductive pillar are arranged in a third direction intersecting the second direction in the plane, and
the first conductive pillar, the third conductive pillar, and the fifth conductive pillar are arranged in the third direction.

14. The memory device according to claim 1, further comprising:
a first conductor layer electrically connected to the first conductive pillar; and
a second conductor layer electrically connected to the second conductive pillar and electrically insulated from the first conductor layer.

15. The memory device according to claim 1, wherein the first charge storage film and the second charge storage film include polysilicon.

16. A memory device comprising:
a first conductive pillar and a second conductive pillar, each extending in a first direction, wherein the first conductive pillar and the second conductive pillar are arranged in a second direction in a plane intersecting the first direction;
a first semiconductor film and a second semiconductor film, each partially surrounding the first conductive pillar at a first position in the first direction;
a third semiconductor film and a fourth semiconductor film, each partially surrounding the second conductive pillar at the first position in the first direction;
a fifth semiconductor film in contact with each of the first semiconductor film and the third semiconductor film; and
a sixth semiconductor film in contact with each of the second semiconductor film and the fourth semiconductor film,
wherein an air gap is provided between the fifth semiconductor film and the sixth semiconductor film and between the first conductive pillar and the second conductive pillar.

17. The memory device according to claim 16, further comprising:
a third conductive pillar and a fourth conductive pillar, each extending in the first direction, wherein the third conductive pillar and the fourth conductive pillar are arranged in a third direction in the plane intersecting the first direction, the third direction being different from the second direction;
a seventh semiconductor film and an eighth semiconductor film, surrounding the third conductive pillar and the fourth conductive pillar, respectively, at the first position in the first direction, wherein
the fifth semiconductor film is in contact with the seventh semiconductor film, and
the sixth semiconductor film is in contact with the eighth semiconductor film.

18. The memory device according to claim 17,
wherein an air gap is provided between the fifth semiconductor film and the sixth semiconductor film and between the third conductive pillar and the fourth conductive pillar.

19. The memory device according to claim 17,
a fifth conductive pillar and a sixth conductive pillar, each extending in the first direction, wherein the fifth conductive pillar and the sixth conductive pillar are arranged in the second direction;
a ninth semiconductor film partially surrounding the fifth conductive pillar at the first position in the first direction;
a tenth semiconductor film partially surrounding the sixth conductive pillar at the first position in the first direction; and
an eleventh semiconductor film in contact with each of the eighth semiconductor film, the ninth semiconductor film, and tenth semiconductor film.

20. The memory device according to claim 19, wherein
an air gap is provided between the fifth conductive pillar and the fourth conductive pillar, and
no air gap is provided between the fifth conductive pillar and the second conductive pillar.
